(19) United States
(12) Patent Application Publication
(10) Pub. No.: US 2026/0247725 A1
(43) Pub. Date: Aug. 20, 2026

(54) PHOTOELECTRIC CONVERSION DEVICE AND PHOTOELECTRIC CONVERSION SYSTEM

(71) Applicant: CANON KABUSHIKI KAISHA, Tokyo (JP)

(72) Inventors: KAZUTAKA OSAWA, Kanagawa (JP); TATSUYA RYOKI, Kanagawa (JP); TATSUHITO GODEN, Tokyo (JP)

(21) Appl. No.: 19/538,623

(22) Filed: Feb. 12, 2026

(30) Foreign Application Priority Data
Feb. 17, 2025 (JP) 2025-023556

(51) Int. Cl. H10F 39/18; H04N 25/616; H04N 25/705; H04N 25/771; H04N 25/79; H10F 39/00

(52) U.S. Cl. CPC H10F 39/1825; H04N 25/616; H04N 25/705; H04N 25/771; H04N 25/79; H10F 39/809; H10F 39/811

(57) ABSTRACT

A photoelectric conversion device includes a pixel unit including a photoelectric conversion element and configured to output a signal according to incident light to the photoelectric conversion element, and a pixel driving circuit configured to drive the pixel unit. The pixel driving circuit includes a circuit including a complementary connection between a first transistor of a first conductivity type provided on a first substrate and a second transistor of a second conductivity type provided on a second substrate.

### BACKGROUND

### Field of the Technology

The present disclosure relates to a photoelectric conversion device and a photoelectric conversion system.

### Description of the Related Art

A technique for improving the performance and function of a photoelectric conversion device by stacking a plurality of substrates has been proposed. For example, in Japanese Patent Laid-Open No. 2024-004794, a photoelectric conversion element that outputs electrons as signal charge and n-channel transistors that transfer the electrons are arranged on a first substrate, and p-channel transistors that amplify the signal charge are arranged on a second substrate, thereby achieving both suppression of 1/f noise and high-speed driving. Further, in Japanese Patent Laid-Open No. 2014-041972, noise caused by a leakage current is reduced by appropriately controlling the relationship between a voltage of a back gate of an amplifier transistor and a voltage of a back gate of a sampling transistor.

However, the techniques described in Japanese Patent Laid-Open No. 2024-004794 and Japanese Patent Laid-Open No. 2014-041972 are mainly intended to reduce noise superimposed on pixel signals, and no particular study has been made on so-called peripheral circuits such as a control circuit for controlling pixels and a signal processing circuit for processing pixel signals.

### SUMMARY

The present disclosure is directed to provide a technique for improving performance of a peripheral circuit and improving quality of a signal output from the photoelectric conversion device and reducing cost in a photoelectric conversion device including a plurality of substrates.

According to one aspect of the present specification, there is provided a photoelectric conversion device including a pixel unit including a photoelectric conversion element and configured to output a signal according to incident light to the photoelectric conversion element, and a pixel driving circuit configured to drive the pixel unit, wherein the pixel driving circuit includes a circuit including a complementary connection between a first transistor of a first conductivity type provided on a first substrate and a second transistor of a second conductivity type provided on a second substrate.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating a schematic configuration of a photoelectric conversion device according to a first embodiment.

FIG. 2 is a schematic diagram illustrating a configuration example of the photoelectric conversion device according to the first embodiment.

FIG. 3 is a diagram illustrating allocation of functional blocks to substrates in the photoelectric conversion device according to the first embodiment.

FIG. 4 is a circuit diagram illustrating a configuration example of a pixel and a pixel memory in the photoelectric conversion device according to the first embodiment.

FIG. 5A, FIG. 5B, and FIG. 5C are circuit diagrams illustrating configuration examples of a pixel vertical scanning circuit in the photoelectric conversion device according to the first embodiment.

FIG. 6A, FIG. 6B, and FIG. 6C are schematic diagrams illustrating scanning images in the row scanning direction in the photoelectric conversion device according to the first embodiment.

FIG. 7 is a diagram illustrating a transfer operation of pixel signals from a pixel unit to a memory unit in block units in the photoelectric conversion device according to the first embodiment.

FIG. 8, FIG. 9, and FIG. 10 are timing charts illustrating a method of driving the photoelectric conversion device according to the first embodiment.

FIG. 11 is a diagram illustrating allocation of functional blocks to substrates in a photoelectric conversion device according to a second embodiment.

FIG. 12 is a circuit diagram illustrating a configuration example of a pixel and a pixel memory in the photoelectric conversion device according to the second embodiment.

FIG. 13A and FIG. 13B are circuit diagrams illustrating a configuration example of a signal processing circuit in the photoelectric conversion device according to the second embodiment.

FIG. 14 and FIG. 15 are circuit diagrams illustrating configuration examples of a logic circuit in the photoelectric conversion device according to the second embodiment.

FIG. 16 is a circuit diagram illustrating a configuration example of a signal processing circuit in a photoelectric conversion device according to a third embodiment.

FIG. 17 is a diagram illustrating allocation of functional blocks to substrates in a photoelectric conversion device according to a fourth embodiment.

FIG. 18 is a block diagram illustrating a schematic configuration of a photoelectric conversion system according to a fifth embodiment.

FIG. 19A is a diagram illustrating a configuration example of a photoelectric conversion system according to a sixth embodiment.

FIG. 19B is a diagram illustrating a configuration example of a movable object according to the sixth embodiment.

FIG. 20 is a block diagram illustrating a schematic configuration of an equipment according to a seventh embodiment.

### DESCRIPTION OF THE EMBODIMENTS

Hereinafter, embodiments of the present disclosure will be described in detail with reference to the accompanying drawings. The following embodiments are intended to embody the technical idea of the present disclosure and do not limit the technology of the present disclosure. Although a plurality of features is described in the embodiments, not all of the plurality of features are essential to the technology of the present disclosure, and the plurality of features may be arbitrarily combined.

In each of the embodiments described below, devices for imaging purposes will be mainly described as an example of a photoelectric conversion device. However, the embodiments are not limited to devices for imaging purposes and may be applied to other photoelectric conversion devices. For example, other examples of the photoelectric conversion device include a ranging device (a device for distance measurement and the like using a focus detection or a time of flight (TOF)), a photometric device (a device for measuring the amount of incident light), and the like.

Note that the conductivity type of each of the transistors described in the embodiments described below is merely an example and is not limited to the conductivity type described in the embodiments. The conductivity type may be appropriately changed with respect to the conductivity type described in the embodiments, and the potentials of the gate, the source, and the drain of the transistor may be appropriately changed in accordance with the change. For example, in the case of a transistor operating as a switch, low-level and high-level of the potential supplied to the gate may be reversed with respect to the description in the embodiments as the conductivity type is changed.

In the following embodiments, connection between elements of a circuit may be described. In this case, even when another element is interposed between the elements of interest, the elements of interest are treated as being connected to each other unless otherwise specified. For example, it is assumed that an element A is connected to one node of a capacitor C having a plurality of nodes, and an element B is connected to the other node of the capacitor. Even in such a case, the element A and the element B are regarded as being connected to each other unless otherwise specified.

### First Embodiment

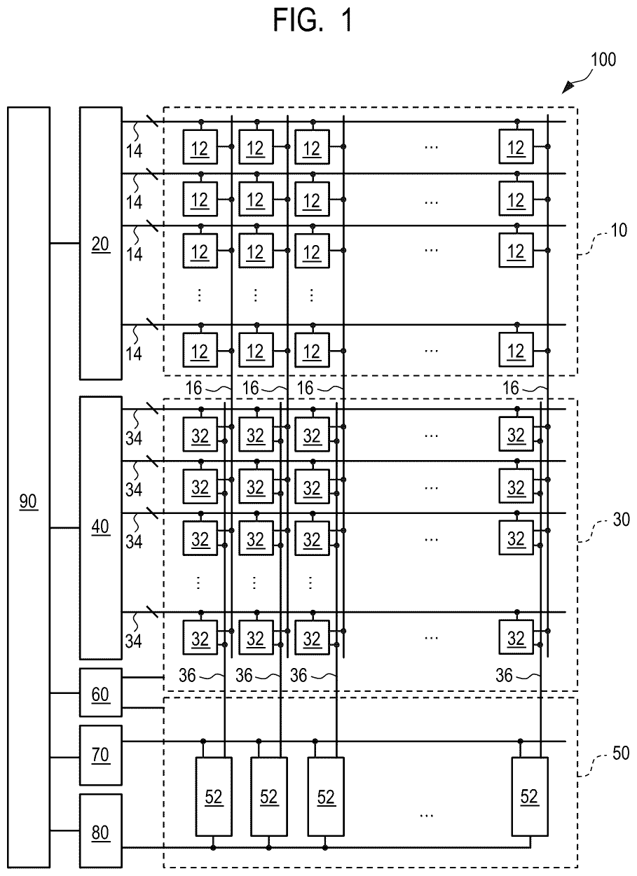

A schematic configuration of a photoelectric conversion device according to a first embodiment will be described with reference to FIG. 1. FIG. 1 is a block diagram illustrating a schematic configuration of a photoelectric conversion device according to the present embodiment.

As illustrated in, e.g., FIG. 1, the photoelectric conversion device 100 includes a pixel unit 10, a pixel vertical scanning circuit 20, a memory unit 30, a memory vertical scanning circuit 40, a signal processing unit 50, a bias generation circuit 60, a reference signal output circuit 70, a column control circuit 80, and a control circuit 90. The bias generation circuit 60 may include bias generation circuits 62, 64, and 66, which will be described later. The control circuit 90 may include a pixel control circuit 92, a memory control circuit 94, and a signal processing control circuit 96, which will be described later.

The pixel unit 10 includes a plurality of pixels 12 arranged in a matrix over a plurality of rows and a plurality of columns. Each of the plurality of pixels 12 includes a photoelectric conversion unit and outputs a pixel signal according to the amount of incident light. Each of the plurality of pixels 12 may include one microlens and a color filter that transmits light in a predetermined wavelength range. In addition to an effective pixel that outputs a pixel signal according to the amount of incident light, an optical black pixel in which a photoelectric conversion unit is shielded, a dummy pixel that does not output a signal, or the like may be arranged in the pixel unit 10. A specific circuit configuration of the pixel 12 will be described later.

In each row of the pixel unit 10, a control line 14 is arranged so as to extend in a first direction (lateral direction in FIG. 1). Each of the control lines 14 is connected to the pixels 12 arranged in the first direction on the corresponding row, respectively, and forms a signal line common to these pixels 12. The first direction in which the control lines 14 extend may be referred to as a row direction or a horizontal direction. Each of the control lines 14 may include a plurality of signal lines. The control lines 14 are connected to the pixel vertical scanning circuit 20.

The memory unit 30 includes a plurality of pixel memories 32 arranged in a matrix over a plurality of rows and a plurality of columns. Each of the plurality of pixel memories 32 includes one or a plurality of memories and holds pixel signals output from the pixel 12. The plurality of pixel memories 32 arranged in the memory unit 30 may be provided so as to correspond to the plurality of pixels 12 arranged in the pixel unit 10 on a one-to-one basis. For example, the number of rows and the number of columns of the pixel array configuring the pixel unit 10 are the same as the number of rows and the number of columns of the pixel memory array configuring the memory unit 30, and each of the plurality of pixel memories 32 may be configured to hold the pixel signal of the pixel 12 having the same row number and column number. A specific circuit configuration of the pixel memory 32 will be described later.

In each row of the memory unit 30, a control line 34 is arranged extending in the first direction. Each of the control lines 34 is connected to the pixel memories 32 arranged in the first direction on the corresponding row, respectively, and forms a signal line common to these pixel memories 32. Each of the control lines 34 may include a plurality of signal lines. The control lines 34 are connected to the memory vertical scanning circuit 40.

The pixel unit 10 and the memory unit 30 are connected to each other via a signal output line 16 provided for each pixel 12 so as to connect the pixel 12 and the pixel memory 32 having the same row number and column number. In FIG. 1, in order to simplify the drawing, each column is described as having a common signal output line 16, but in practice, each pixel 12 is connected to one corresponding pixel memory 32 via one signal output line 16. However, the signal output line 16 may be arranged in each column of the pixel unit 10 and the memory unit 30 as illustrated in FIG. 1 and may constitute a signal line common to the pixels 12 and the pixel memory 32 in the corresponding column. In this case, the signals of the pixels 12 are sequentially read out to the signal output line 16 in units of rows, and the signals output to the signal output line 16 are sequentially written into the pixel memory 32 in units of rows, whereby the signals may be transferred from the pixel unit 10 to the memory unit 30.

A signal output line 36 is arranged in each column of the memory unit 30 so as to extend in a second direction (vertical direction in FIG. 1). Each of the signal output lines 36 is connected to the pixel memories 32 arranged in the second direction on the corresponding column, respectively, and forms a signal line common to these pixel memories 32. The signal output lines 36 are connected to the signal processing unit 50.

The pixel vertical scanning circuit 20 is a pixel driving circuit that drives the pixels 12. The pixel vertical scanning circuit 20 has a function of generating a control signal for driving the pixels 12 in accordance with a control signal from the control circuit 90 and outputting the generated control signal to the pixel unit 10. The pixel vertical scanning circuit 20 may be configured by using a logic circuit such as a shift register or an address decoder. The pixel vertical scanning circuit 20 may perform an operation of sequentially outputting control signals to the control lines 14 of each row and sequentially driving the pixels 12 of the pixel unit 10 in units of rows, that is, so-called vertical scanning. The pixel signals read out from the pixels 12 in units of rows are input to the memory unit 30 via the signal output lines 16. Alternatively, the transfer of the pixel signals from the pixel unit 10 to the memory unit 30 may be performed collectively or in units of blocks. When pixel signals are transferred collectively or in units of blocks, the control signals may be output collectively or in units of blocks to the control lines 14 of each row.

The memory vertical scanning circuit 40 is a memory driving circuit that drives the pixel memories 32. The memory vertical scanning circuit 40 has a function of generating a control signal for driving the pixel memories 32 in accordance with a control signal from the control circuit 90 and outputting the generated control signal to the memory unit 30. The memory vertical scanning circuit 40 may be configured by using a logic circuit such as a shift register or an address decoder. The memory vertical scanning circuit 40 may perform an operation of sequentially outputting control signals to the control lines 34 of each row and sequentially driving the pixel memories 32 of the memory unit 30 in units of rows, that is, so-called vertical scanning. The pixel signals read out from the pixel memory 32 in units of rows are input to the signal processing unit 50 via the signal output lines 36.

The signal processing unit 50 includes a plurality of signal processing circuits 52 corresponding to each column of the memory unit 30. The signal processing circuit 52 of each column is connected to the signal output line 36 of the corresponding column. Each of the plurality of signal processing circuits 52 performs predetermined signal processing on the pixel signal read out from the pixel memory 32 of the corresponding column. Examples of the processing performed by the signal processing circuit 52 include signal processing such as amplification processing and analog-to-digital (AD) conversion processing. In order to realize these functions, the signal processing circuit 52 may include a comparator circuit that performs a comparison operation between a pixel signal read out from the pixel memory 32 and a reference signal whose voltage temporally changes, a driving circuit such as a current source, an arithmetic processing circuit that performs data arithmetic processing, and the like. Note that the arithmetic processing circuits are not required to be provided for the respective columns, and signals of the respective columns may be sequentially input to one arithmetic processing circuit.

The signal processing unit 50 may further include an output circuit (not illustrated) for outputting the pixel signal after the arithmetic processing to the outside of the photoelectric conversion device 100. The external interface circuit included in the output circuit unit is not particularly limited. As the external interface circuit, for example, a serializer/deserializer (SerDes) transmission circuit may be applied. Examples of the SerDes transmission circuit include a low voltage differential signaling (LVDS) circuit and a scalable low voltage signaling (SLVS) circuit.

The bias generation circuit 60 has a function of generating a predetermined bias voltage supplied to the pixel unit 10, the memory unit 30, and the signal processing unit 50. The bias voltage generated in the bias generation circuit 60 will be described later.

The reference signal output circuit 70 is connected to the signal processing circuit 52 of each column of the signal processing unit 50. The reference signal output circuit 70 has a function of outputting a reference signal used for AD conversion to the signal processing unit 50 in accordance with a control signal from the control circuit 90. The reference signal used for AD conversion may have a predetermined amplitude according to the range of the pixel signal and may be a signal whose signal level changes with time. Although the reference signal is not particularly limited, for example, a ramp signal in which the signal level monotonically increases or monotonically decreases with time may be applied. The change in the signal level does not necessarily have to be continuous and may be stepwise. In addition, the change in the signal level does not necessarily need to be linear with respect to time and may be curved with respect to time (for example, a sine wave or a cosine wave). The reference signal output circuit 70 may be configured to generate and output a reference signal or may be configured to buffer and output a reference signal generated outside the photoelectric conversion device.

The column control circuit 80 has a function of generating a control signal for reading out a pixel signal from the signal processing circuit 52 of the signal processing unit 50 in accordance with a control signal from the control circuit 90 and outputting the generated control signal to the signal processing circuit 52. The column control circuit 80 sequentially scans the signal processing circuit 52 of the signal processing unit 50 and sequentially outputs the pixel signals held therein to the outside of the photoelectric conversion device. The column control circuit 80 may be configured using a logic circuit such as a shift register or an address decoder. A logic circuit such as a shift register or an address decoder may be used as the column control circuit 80.

The control circuit 90 has a function of generating control signals for controlling the operations of the above-described functional blocks and outputting the generated control signals to these functional blocks. At least a part of the control signals for controlling the operation of these functional blocks may be supplied from the outside of the photoelectric conversion device 100.

In this specification, functional blocks excluding the pixel unit 10 and the memory unit 30 may be collectively referred to as a peripheral circuit. The peripheral circuit is typically a functional block that drives the pixels 12 and processes signals read out from the pixels 12.

The power supply voltage of at least a part of the transistors constituting the column control circuit 80 and the control circuit 90 is a relatively low voltage such as 1.8 V. On the other hand, the power supply voltage of the transistors constituting the pixel 12, the pixel memory 32, the signal processing circuit 52, the pixel vertical scanning circuit 20, the memory vertical scanning circuit 40, the bias generation circuits 64 and 66, and the reference signal output circuit 70 is a relatively high voltage such as 3.3 V. Here, the withstand voltage of the transistor is mainly determined by a thickness of a gate insulating film, and the thickness of the gate insulating film of the transistor driven at 3.3 V is larger than the thickness of the gate insulating film of the transistor driven at 1.8 V.

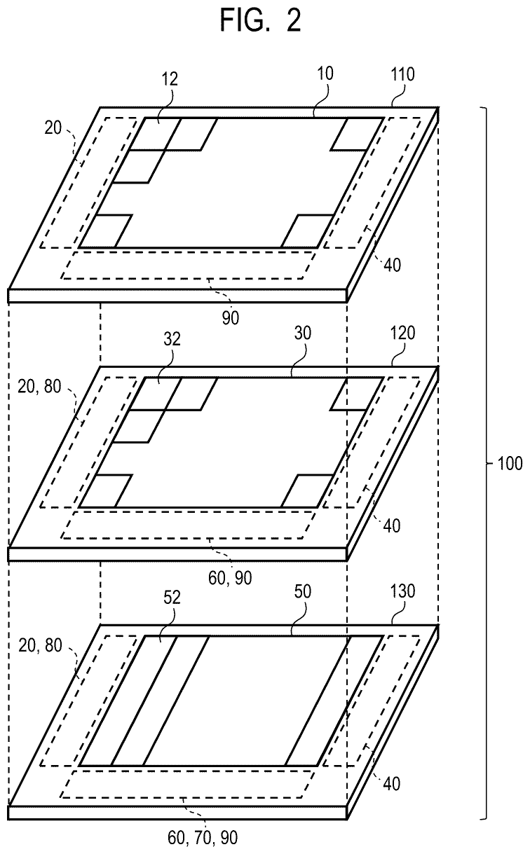

The photoelectric conversion device 100 according to the present embodiment may be configured as a stacked-type photoelectric conversion device in which a plurality of substrates is stacked. FIG. 2 is a schematic diagram illustrating a schematic configuration of the photoelectric conversion device according to the present embodiment. As illustrated in, e.g., FIG. 2, the photoelectric conversion device 100 according to the present embodiment may be configured by stacking three substrates of a first substrate 110, a second substrate 120, and a third substrate 130 and electrically connecting the substrates to each other.

In the configuration example of FIG. 2, for example, the pixel unit 10, and at least a part of the pixel vertical scanning circuit 20, the memory vertical scanning circuit 40, and the control circuit 90 may be arranged on the first substrate 110. On the second substrate 120, for example, the memory unit 30, and at least a part of the pixel vertical scanning circuit 20, the memory vertical scanning circuit 40, the bias generation circuit 60, the column control circuit 80, and the control circuit 90 may be arranged. On the third substrate 130, for example, the signal processing unit 50, the reference signal output circuit 70, and all or a part of the bias generation circuit 60, the column control circuit 80, and the control circuit 90 may be arranged.

The pixel unit 10, the memory unit 30, and the signal processing unit 50 may be provided on the first substrate 110, the second substrate 120, and the third substrate 130, respectively, so as to overlap each other in a plan view. In this specification, the plan view refers to a view from a direction perpendicular to the light incident surface of the first substrate 110. When the light incident surface of the semiconductor layer is a rough surface as viewed microscopically, the plan view is defined with reference to the light incident surface of the semiconductor layer as viewed macroscopically.

The pixel vertical scanning circuit 20, the memory vertical scanning circuit 40, the bias generation circuit 60, the reference signal output circuit 70, the column control circuit 80, and the control circuit 90 may be arranged around the pixel unit 10, the memory unit 30, or the signal processing unit 50 of each substrate in the plan view. These functional blocks may be provided on one substrate or may be provided by being divided into a plurality of substrates. The arrangement location of each functional block on each substrate is not limited to the example illustrated in FIG. 2.

By configuring the stacked-type photoelectric conversion device 100, it is possible to increase the degree of integration of elements and achieve higher functionality. In particular, by arranging the pixel unit 10, the memory unit 30, and the signal processing unit 50 on different substrates, the photoelectric conversion elements may be arranged at high density without sacrificing the light receiving area of the photoelectric conversion elements included in each pixel 12, and the photon detection efficiency may be improved. In addition, since the signal processing unit 50 is arranged on another substrate, the circuit area of the signal processing unit 50 may be increased, and the photoelectric conversion device may have higher functionality.

Although FIG. 2 illustrates a configuration in which three substrates of the first substrate 110, the second substrate 120, and the third substrate 130 are stacked, a configuration in which two or four or more substrates are stacked may be employed. In FIG. 2, a diced chip is assumed as the first substrate 110, the second substrate 120, and the third substrate 130, but the first substrate 110, the second substrate 120, and the third substrate 130 are not limited to chips. For example, each of the first substrate 110, the second substrate 120, and the third substrate 130 may be a wafer. In addition, the first substrate 110, the second substrate 120, and the third substrate 130 may be stacked in a wafer state and then diced or may be stacked and bonded after being formed into chips.

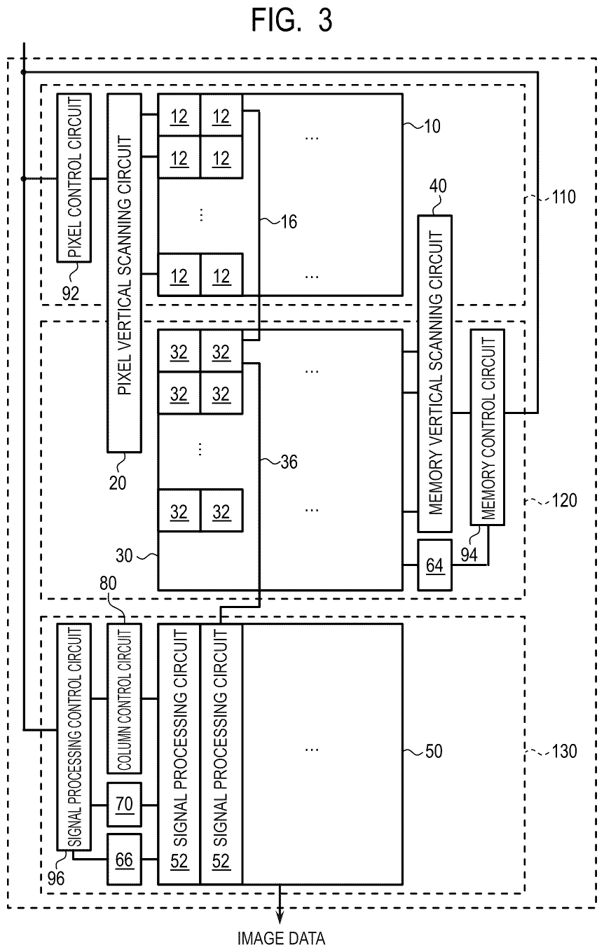

Next, allocation of each functional block to each substrate in the photoelectric conversion device according to the present embodiment will be described with reference to FIG. 3. FIG. 3 is a diagram illustrating allocation of each functional block to each substrate in the photoelectric conversion device according to the present embodiment.

As described above, the photoelectric conversion device according to the present embodiment is configured by stacking three substrates of the first substrate 110, the second substrate 120, and the third substrate 130. Among the functional blocks described above, the pixel unit 10, a part of the pixel vertical scanning circuit 20, a part of the memory vertical scanning circuit 40, and a pixel control circuit 92 which is a part of the control circuit 90 are arranged on the first substrate 110. Among the functional blocks described above, the memory unit 30, another part of the pixel vertical scanning circuit 20, another part of the memory vertical scanning circuit 40, the bias generation circuit 64, and the memory control circuit 94 which is a part of the control circuit 90 are arranged on the second substrate 120. Among the functional blocks described above, the signal processing unit 50, the bias generation circuit 66, the reference signal output circuit 70, the column control circuit 80, and the signal processing control circuit 96, which is a part of the control circuit 90, are arranged on the third substrate 130.

The pixel control circuit 92 generates a control signal for driving the pixel vertical scanning circuit 20 in accordance with a signal input from the outside of the photoelectric conversion device. The pixel vertical scanning circuit 20 controls the plurality of pixels 12 of the pixel unit 10 in units of rows in accordance with the control signal from the pixel control circuit 92. Each pixel 12 outputs a pixel signal, which is an analog signal corresponding to the amount of incident light, to the second substrate 120 via the signal output line 16 in accordance with the control signal from the pixel vertical scanning circuit 20. The pixel signals output from the pixels 12 are input to the corresponding pixel memories 32 among the plurality of pixel memories 32 included in the memory unit 30 of the second substrate 120.

The memory control circuit 94 generates control signals for driving the memory vertical scanning circuit 40 and the bias generation circuit 64 in accordance with a signal input from the outside of the photoelectric conversion device. The memory vertical scanning circuit 40 controls the plurality of pixel memories 32 of the memory unit 30 in units of rows in accordance with the control signal from the memory control circuit 94. Each pixel memory 32 holds the pixel signal input via the signal output line 16 or outputs the pixel signal held therein to the third substrate 130 via the signal output line 36 in accordance with the control signal from the memory vertical scanning circuit 40. The pixel signal output from the pixel memory 32 is input to the signal processing circuit 52 of the corresponding column among the plurality of signal processing circuits 52 constituting the signal processing unit 50 of the third substrate 130.

The signal processing control circuit 96 generates a control signal for driving the column control circuit 80, the bias generation circuit 66, and the reference signal output circuit 70 in accordance with a signal input from the outside of the photoelectric conversion device. The column control circuit 80, the bias generation circuit 66, and the reference signal output circuit 70 control the signal processing circuit 52 of each column in accordance with the control signal from the signal processing control circuit 96 and perform predetermined arithmetic processing on the pixel signal read out from the memory unit 30. The pixel signal after the arithmetic processing is output to the outside of the photoelectric conversion device via an output circuit (not illustrated).

Here, as illustrated in FIG. 3, the pixel vertical scanning circuit 20 and the memory vertical scanning circuit 40 are provided across the first substrate 110 and the second substrate 120. More specifically, among the circuit elements constituting the pixel vertical scanning circuit 20 and the memory vertical scanning circuit 40, the n-channel transistors are arranged on the first substrate 110, and the p-channel transistors are arranged on the second substrate 120.

In the case where the photoelectric conversion device is configured by two substrates, for example, the first substrate 110 and the third substrate 130, the functional blocks arranged on the second substrate 120 may be distributed to the first substrate 110 and the third substrate 130. For example, the memory unit 30, the bias generation circuit 64, and the memory control circuit 94 may be arranged on the first substrate 110, and a part of the pixel vertical scanning circuit 20 and the memory vertical scanning circuit 40 may be arranged on the third substrate 130. In this case, among the circuit elements constituting the pixel vertical scanning circuit 20 and the memory vertical scanning circuit 40, the n-channel transistors may be arranged on the first substrate 110, and the p-channel transistors may be arranged on the third substrate 130.

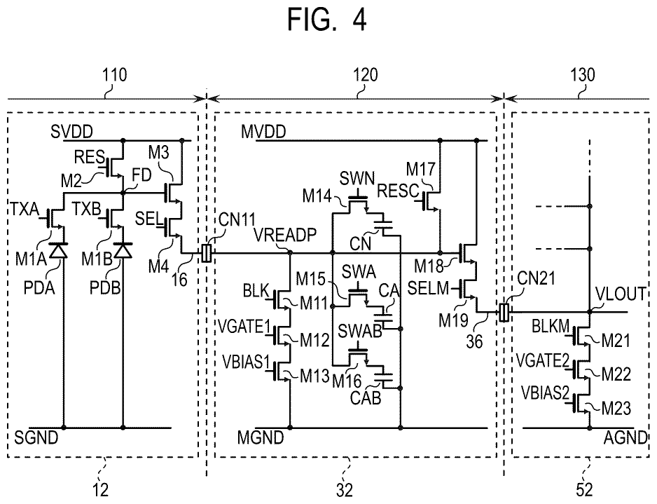

Next, the circuit configuration of the pixel 12 and the pixel memory 32 will be described more specifically with reference to FIG. 4. FIG. 4 is an equivalent circuit diagram illustrating a configuration example of the pixel 12 and the pixel memory 32 in the photoelectric conversion device according to the present embodiment.

Each of the pixels 12 included in the pixel unit 10 may include photoelectric conversion elements PDA and PDB, transfer transistors M1A and M1B, a reset transistor M2, an amplifier transistor M3, and a select transistor M4, for example, as illustrated in FIG. 4.

The photoelectric conversion elements PDA and PDB are, for example, photodiodes. The photoelectric conversion element PDA has an anode connected to the ground voltage node (voltage SGND) and a cathode connected to a source of the transfer transistor M1A. The photoelectric conversion element PDB has an anode connected to the ground voltage node (voltage SGND) and a cathode connected to a source of the transfer transistor M1B. Drains of the transfer transistors M1A and M1B are connected to a source of the reset transistor M2 and a gate of the amplifier transistor M3. A node FD to which the drains of the transfer transistors M1A and M1B, the source of the reset transistor M2, and the gate of the amplifier transistor M3 are connected is a so-called floating diffusion. The floating diffusion includes a capacitance component (floating diffusion capacitance) and has a function as a charge holding portion. The floating diffusion capacitance may include a gate capacitance, a p-n junction capacitance, an interconnection capacitance, and the like coupled to the transistor. A drain of the reset transistor M2 and a drain of the amplifier transistor M3 are connected to a node to which the power supply voltage (voltage SVDD) is supplied. A source of the amplifier transistor M3 is connected to a drain of the select transistor M4. A source of the select transistor M4 is connected to the signal output line 16. The signal output line 16 is connected to a node VREADP, which is an input node of the pixel memory 32, via a connection portion CN11, which is one of electrical connection portions between the first substrate 110 and the second substrate 120.

In the case of the configuration of the pixel 12 of FIG. 2, the control line 14 of each row includes four signal lines including a signal line connected to a gate of the transfer transistor M1A, a signal line connected to a gate of the transfer transistor M1B, a signal line connected to a gate of the reset transistor M2, and a signal line connected to a gate of the select transistor M4. A control signal TXA is supplied from the pixel vertical scanning circuit 20 to the gate of the transfer transistor M1A. A control signal TXB is supplied from the pixel vertical scanning circuit 20 to the gate of the transfer transistor M1B. A control signal RES is supplied from the pixel vertical scanning circuit 20 to the gate of the reset transistor M2. A control signal SEL is supplied from the pixel vertical scanning circuit 20 to the gate of the select transistor M4. In the case where each transistor is formed of an n-channel transistor, when a high-level control signal is supplied from the pixel vertical scanning circuit 20, the corresponding transistor is turned on. When a low-level control signal is supplied from the pixel vertical scanning circuit 20, the corresponding transistor is turned off.

The present embodiment will be described on the assumption that electrons among electron-hole pairs generated in the photoelectric conversion elements PDA and PDB by light incidence are used as the signal charge. When electrons are used as the signal charge, each transistor constituting the pixel 12 may be formed of an n-channel MOS transistor. However, the signal charge is not limited to electrons, and holes may be used as the signal charge. When holes are used as the signal charge, the conductivity type of each transistor may be opposite to that described in the present embodiment. The names of the source and the drain of the MOS transistor may vary depending on the conductivity type of the transistor and the function of interest. Some or all of the names of the source and the drain used in the present embodiment may be referred to as reverse names.

The photoelectric conversion elements PDA and PDB convert (photoelectrically convert) the incident light into charge of an amount corresponding to the amount of the incident light and accumulate the generated charge. The transfer transistor M1A transfers the charge held by the photoelectric conversion element PDA to the node FD by turning on. The transfer transistor M1B transfers the charge held by the photoelectric conversion element PDB to the node FD by turning on. The charges transferred from the photoelectric conversion elements PDA and PDB are held in the capacitance component (floating diffusion capacitance) of the node FD. As a result, the node FD becomes a potential corresponding to the amount of charge transferred from the photoelectric conversion elements PDA and PDB by charge-voltage conversion by the floating diffusion capacitance.

The select transistor M4 connects the amplifier transistor M3 to the signal output line 16 by turning on. The amplifier transistor M3 has the drain to which the voltage SVDD is supplied and the source to which a bias current is supplied via the select transistor M4 and constitutes an amplifier unit (source follower circuit) having the gate as an input node. Accordingly, the amplifier transistor M3 outputs a signal based on the voltage of the node FD to the signal output line 16 via the select transistor M4. In this sense, the amplifier transistor M3 and the select transistor M4 constitute an output unit that outputs a pixel signal according to the amount of charge held in the node FD.

The reset transistor M2 has a function of controlling supply of a voltage (voltage SVDD) for resetting the node FD as a charge holding unit to the FD node. The reset transistor M2 resets the node FD to a voltage corresponding to the voltage SVDD by turning on. At this time, it is also possible to reset the photoelectric conversion element PDA to a voltage corresponding to the voltage SVDD by simultaneously turning on the transfer transistor M1A. Further, by simultaneously turning on the transfer transistor M1B, the photoelectric conversion element PDB may be reset to a voltage corresponding to the voltage SVDD.

The pixel 12 including a plurality of photoelectric conversion elements as in the present embodiment may output a plurality of types of signals. Such a pixel 12 is capable of outputting a first signal corresponding to the amount of charge generated by the first number of photoelectric conversion elements among the plurality of photoelectric conversion elements and a second signal corresponding to the amount of charge generated by the second number of photoelectric conversion elements larger than the first number among the plurality of photoelectric conversion elements. For example, when the pixel 12 includes two photoelectric conversion elements PDA and PDB, the first signal may be an SA-signal to be described later, and the second signal may be an SAB-signal to be described later.

As illustrated in FIG. 4, each of the pixel memories 32 included in the memory unit 30 includes a current source switch transistor M11, a cascode transistor M12, a pixel current source transistor M13, and sampling transistors M14, M15, and M16. Each of the pixel memories 32 further includes hold capacitors CN, CA, and CAB, a reset transistor M17, an amplifier transistor M18, and a select transistor M19. Each of the hold capacitors CN, CA, and CAB is a holding portion of temporally holding a signal output from the pixel 12.

A drain of the current source switch transistor M11, sources of the sampling transistors M14, M15, and M16, a source of the reset transistor M17, and a gate of the amplifier transistor M18 are connected to the node VREADP. A source of the current source switch transistor is connected to a drain of the cascode transistor M12. A source of the cascode transistor M12 is connected to a drain of the pixel current source transistor M13. A drain of the sampling transistor M14 is connected to one terminal of the hold capacitor CN. A drain of the sampling transistor M15 is connected to one terminal of the hold capacitor CA. A drain of the sampling transistor M16 is connected to one terminal of the hold capacitor CAB. A source of the pixel current source transistor M13 and the other terminals of the hold capacitors CN, CA, and CAB are connected to the ground voltage node (voltage MGND). A drain of the reset transistor M17 and a drain of the amplifier transistor M18 are connected to the power supply voltage node (voltage MVDD). A source of the amplifier transistor M18 is connected to a drain of the select transistor M19. A source of the select transistor M19 is connected to the signal output line 36. The signal output line 36 is connected to a node VLOUT of the signal processing circuit 52 via a connection portion CN21, which is one of electrical connection portions between the second substrate 120 and the third substrate 130.

In the case of the configuration of the pixel memory 32 of FIG. 2, the control line 34 of each row includes five signal lines including signal lines connected to gates of the sampling transistors M14, M15, and M16, a signal line connected to a gate of the reset transistor M17, and a signal line connected to a gate of the select transistor M19. A control signal SWN is supplied from the memory vertical scanning circuit 40 to the gate of the sampling transistor M14. A control signal SWA is supplied from the memory vertical scanning circuit 40 to the gate of the sampling transistor M15. A control signal SWAB is supplied from the memory vertical scanning circuit 40 to the gate of the sampling transistor M16. A control signal RESC is supplied from the memory vertical scanning circuit 40 to the gate of the reset transistor M17. A control signal SELM is supplied from the memory vertical scanning circuit 40 to the gate of the select transistor M19. In the case where each transistor is formed of an n-channel transistor, when a high-level control signal is supplied from the memory vertical scanning circuit 40, the corresponding transistor is turned on. When a low-level control signal is supplied from the memory vertical scanning circuit 40, the corresponding transistor is turned off.

The current source switch transistor M11, the cascode transistor M12, and the pixel current source transistor M13 constitute a current source for supplying a bias current to the amplifier transistor M3 of the pixel 12. A control signal BLK is supplied from the memory vertical scanning circuit 40 to a gate of the current source switch transistor M11. A voltage VGATE1 is supplied from the bias generation circuit 64 to a gate of the cascode transistor M12. A voltage VBIAS1 is supplied from the bias generation circuit 64 to a gate of the pixel current source transistor M13.

Each of the signal processing circuits 52 included in the signal processing unit 50 includes a current source switch transistor M21, a cascode transistor M22, and a pixel memory current source transistor M23, for example, as illustrated in FIG. 4. Although the signal processing circuit 52 may include other circuits according to predetermined arithmetic processing performed by the signal processing unit 50, such as an AD conversion circuit, only components related to the operation of the pixel memory 32 will be described here.

A drain of the current source switch transistor M21 is connected to the node VLOUT. A source of the current source switch transistor M21 is connected to a drain of the cascode transistor M22. A source of the cascode transistor M22 is connected to a drain of the pixel memory current source transistor M23. A source of the pixel memory current source transistor M23 is connected to the ground voltage node (voltage AGND).

The current source switch transistor M21, the cascode transistor M22, and the pixel memory current source transistor M23 constitute a current source for supplying a bias current to the amplifier transistor M18 of the pixel memory 32. A control signal BLKM is supplied from the column control circuit 80 to a gate of the current source switch transistor M21. A voltage VGATE2 is supplied from the bias generation circuit 66 to a gate of the cascode transistor M22. A voltage VBIAS2 is supplied from the bias generation circuit 66 to a gate of the pixel memory current source transistor M23.

The node VLOUT is connected to the select transistors M19 of the plurality of pixel memories 32 arranged in the same column.

The reset transistor M17 sets the node VREADP to a voltage corresponding to the voltage MVDD by turning on. When the sampling transistor M14 is turned on, a signal read out from the pixel 12 to the node VREADP is written to the hold capacitor CN, or a signal held by the hold capacitor CN is read out to the node VREADP. When the sampling transistor M15 is turned on, a signal read out from the pixel 12 to the node VREADP is written to the hold capacitor CA, or a signal held by the hold capacitor CA is read out to the node VREADP. When the sampling transistor M16 is turned on, a signal read out from the pixel 12 to the node VREADP is written to the hold capacitor CAB, or a signal held by the hold capacitor CAB is read out to the node VREADP.

The select transistor M19 connects the amplifier transistor M18 to the signal output line 36 by turning on. The amplifier transistor M18 has the drain to which the voltage MVDD is supplied and the source to which the bias current is supplied via the select transistor M19 and constitutes an amplifier unit (source follower circuit) having the gate as an input node. Accordingly, the amplifier transistor M18 outputs a signal based on the voltage of the node VREADP to the signal output line 36 via the select transistor M19. In this sense, the amplifier transistor M18 and the select transistor M19 constitute an output unit that outputs a signal according to the voltage of the node VREADP.

In the configuration example of FIG. 4, the voltage SGND of the ground voltage node of the first substrate 110, the voltage MGND of the ground voltage node of the second substrate 120, and the voltage AGND of the ground voltage node of the third substrate 130 are described as different power supply voltages. This is because the influence of power supply fluctuations on other circuits may be reduced by separating the power supplies that generate the voltages SGND, MGND, and AGND from each other. However, the power supplies for generating the voltages SGND, MGND, and AGND are not necessarily required to be separate, and may be common. The voltages SGND, MGND, and AGND may be the same or different. In the configuration example of FIG. 4, the case where one pixel 12 includes two photoelectric conversion elements PDA and PDB is illustrated, but the number of photoelectric conversion elements included in one pixel 12 may be one or three or more. In addition, the cascode transistors M12 and M22 are transistors that suppress a change in current due to a change in the drain voltage of the pixel current source transistor M13 or the pixel memory current source transistor M23, and are not necessarily provided when a change in current due to a change in the drain voltage is small.

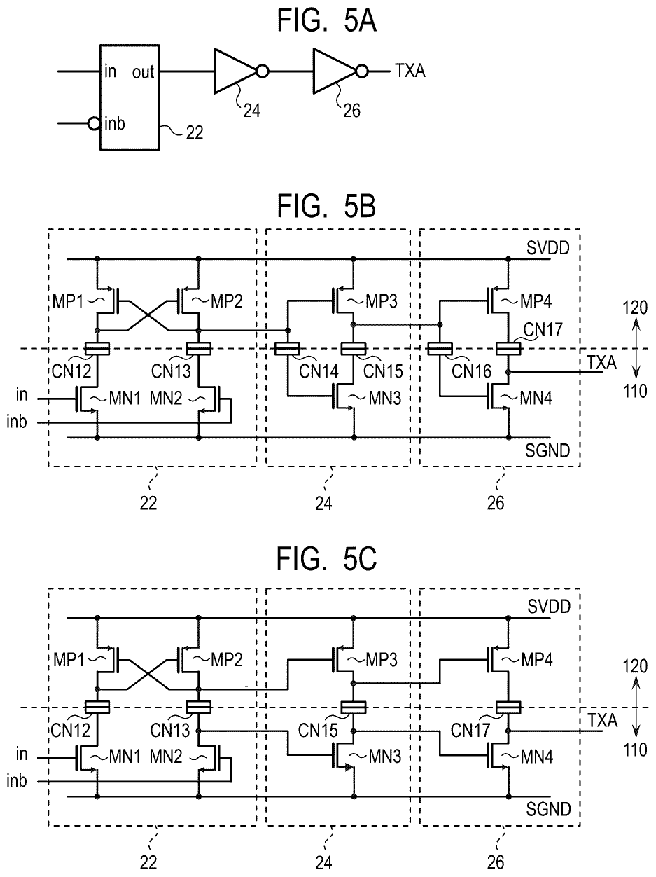

Next, a configuration example of the pixel vertical scanning circuit 20 and the memory vertical scanning circuit will be described with reference to FIG. 5A to FIG. 5C.

As described above, the pixel vertical scanning circuit 20 is a circuit that outputs the control signals TXA, TXB, RES, and SEL for driving the pixels 12. The pixel vertical scanning circuit 20 generates control signals TXA, TXB, RES, and SEL based on the pixel scanning signal input from the pixel control circuit 92. The pixel control circuit 92 generates the pixel scanning signal based on a signal input from the outside of the photoelectric conversion device. Here, while the pixel scanning signal is, for example, a 1.8 V-level signal, the control signals TXA, TXB, RES, and SEL output from the pixel vertical scanning circuit 20 are, for example, a 3.3 V-level signal. Therefore, the pixel vertical scanning circuit 20 is required to convert the pixel scanning signal of the 1.8 V-level into the control signals TXA, TXB, RES, and SEL of the 3.3 V-level and output them.

Similarly, as described above, the memory vertical scanning circuit 40 is a circuit that outputs the control signals BLK, SWN, SWA, SWAB, RESC, and SELM for driving the pixel memory 32. The memory vertical scanning circuit 40 generates control signals BLK, SWN, SWA, SWAB, RESC, and SELM based on the memory scanning signal input from the memory control circuit 94. The memory control circuit 94 generates a memory scanning signal based on a signal input from the outside of the photoelectric conversion device. Here, while the memory scanning signal is, for example, a 1.8 V-level signal, the control signals BLK, SWN, SWA, SWAB, RESC, and SELM output from the memory scanning circuit are, for example, a 3.3 V-level signal. Therefore, the memory vertical scanning circuit 40 is required to convert the memory scanning signal of the 1.8 V-level into the control signals BLK, SWN, SWA, SWAB, RESC, and SELM of the 3.3 V-level and output them.

FIG. 5A to FIG. 5C are circuit diagrams illustrating a part of the pixel vertical scanning circuit 20 in the photoelectric conversion device according to the present embodiment. FIG. 5A is a circuit diagram illustrating a configuration example of a block that outputs the control signal TXA in the pixel vertical scanning circuit 20. FIG. 5B is an example of a circuit diagram in which the circuit of FIG. 5A is rewritten with transistor-level elements. FIG. 5C is another example of a circuit diagram in which the circuit of FIG. 5A is rewritten with transistor-level elements. The block that outputs the other control signals TXB, RES, and SEL may have the same configuration as the block that outputs the control signal TXA. The same may be applied to the blocks that output the control signals BLK, SWN, SWA, SWAB, RESC, and SELM of the memory vertical scanning circuit 40.

The pixel vertical scanning circuit 20 may include a voltage conversion circuit 22 and inverters 24 and 26. The voltage conversion circuit 22 includes input terminals in and inb and an output terminal out. The output terminal out of the voltage conversion circuit is connected to an input terminal of the inverter 24. An output terminal of the inverter 24 is connected to an input terminal of the inverter 26. An output terminal of the inverter 26 is an output terminal of the control signal TXA.

A pixel scanning signal generated based on an output signal from the pixel control circuit 92 is input to the input terminal in of the voltage conversion circuit 22. An inverted signal of the pixel scanning signal is input to the input terminal inb of the voltage conversion circuit 22. The voltage conversion circuit 22 converts the voltage value of the pixel scanning signal into a suitable voltage value as the control signal TXA and outputs the converted voltage value from the output terminal out. The inverters 24 and 26 buffer the output signal of the voltage conversion circuit 22 and output it as a control signal TXA.

Here, the voltage conversion circuit 22 and the inverters 24 and 26 may be configured by a circuit including a complementary connection of an n-channel transistor and a p-channel transistor, that is, a so-called complementary metal-oxide-semiconductor (CMOS) circuit.

The voltage conversion circuit 22 may include, as illustrated in, e.g., FIG. 5B, n-channel transistors MN1 and MN2 arranged on the first substrate 110 and p-channel transistors MP1 and MP2 arranged on the second substrate 120. Sources of the n-channel transistors MN1 and MN2 are connected to the ground voltage node (voltage SGND). A drain of the n-channel transistor MN1 is connected to a drain of the p-channel transistor MP1 and a gate of the p-channel transistor MP2 via a connection portion CN12, which is one of electrical connection portions between the first substrate 110 and the second substrate 120. A drain of the n-channel transistor MN2 is connected to a drain of the p-channel transistor MP2 and a gate of the p-channel transistor MP1 via a connection portion CN13, which is one of the electrical connection portions between the first substrate 110 and the second substrate 120. Sources of the p-channel transistors MP1 and MP2 are connected to the power supply voltage node (voltage SVDD). A gate of the n-channel transistor MN1 serves as the input terminal in, a gate of the n-channel transistor MN2 serves as the input terminal inb, and the connection node between the drain of the n-channel transistor MN2, the gate of the p-channel transistor MP1, and the drain of the p-channel transistor MP2 serves as the output terminal out.

The inverter 24 may include, as illustrated in, e.g., FIG. 5B, an n-channel transistor MN3 arranged on the first substrate 110 and a p-channel transistor MP3 arranged on the second substrate 120. A source of the n-channel transistor MN3 is connected to the ground voltage node (voltage SGND). A drain of the n-channel transistor MN3 is connected to a drain of the p-channel transistor MP3 via a connection portion CN15, which is one of the electrical connection portions between the first substrate 110 and the second substrate 120. A gate of the n-channel transistor MN3 is connected to a gate of the p-channel transistor MP3 via a connection portion CN14, which is one of the electrical connection portions between the first substrate 110 and the second substrate 120. A source of the p-channel transistor MP3 is connected to the power supply voltage node (voltage SVDD). A connection node between the gate of the n-channel transistor MN3 and the gate of the p-channel transistor MP3 serves as the input terminal connected to the voltage conversion circuit 22, and a connection node between the drain of the n-channel transistor MN3 and the drain of the p-channel transistor MP3 serves as the output terminal.

The inverter 26 may include, as illustrated in, e.g., FIG. 5B, an n-channel transistor MN4 arranged on the first substrate 110 and a p-channel transistor MP4 arranged on the second substrate 120. A source of the n-channel transistor MN4 is connected to the ground voltage node (voltage SGND). A drain of the n-channel transistor MN4 is connected to a drain of the p-channel transistor MP4 via a connection portion CN17, which is one of the electrical connection portions between the first substrate 110 and the second substrate 120. A gate of the n-channel transistor MN4 is connected to a gate of the p-channel transistor MP4 via a connection portion CN16, which is one of the electrical connection portions between the first substrate 110 and the second substrate 120. A source of the p-channel transistor MP4 is connected to the power supply voltage node (voltage SVDD). A connection node between the gate of the n-channel transistor MN4 and the gate of the p-channel transistor MP4 serves as the input terminal connected to the inverter 24, and a connection node between the drain of the n-channel transistor MN4 and the drain of the p-channel transistor MP4 serves as the output terminal.

The circuit illustrated in FIG. 5C has the same basic connection relationship as that of the circuit illustrated in FIG. 5B, except that the electrical connection between the first substrate 110 and the second substrate 120 is different.

In the circuit of FIG. 5C, a connection node between the gate of the n-channel transistor MN3 and the drain of the n-channel transistor MN2 and a connection node between the gates of the p-channel transistors MP1 and MP3 and the drain of the p-channel transistor MP2 are connected via a connection portion CN13. A connection node between the gate of the n-channel transistor MN4 and the drain of the n-channel transistor MN3 and a connection node between the gate of the p-channel transistor MP4 and the drain of the p-channel transistor MP3 are connected to each other via a connection portion CN15.

In the circuit of FIG. 5B, in a state before the first substrate 110 and the second substrate 120 are bonded to each other, the connection portion CN14 is connected to only the gate of the n-channel transistor MN3, and the connection portion CN16 is connected to only the gate of the n-channel transistor MN4. That is, the gates of the n-channel transistors MN3 and MN4 are in a floating state. Therefore, when the connection portion CN14 or the connection portion CN16 is exposed to plasma in the manufacturing process of the first substrate 110, dielectric breakdown of the gate insulating films of the n-channel transistors MN3 and MN4 may occur due to charge-up caused by plasma.

In this regard, in the circuit of FIG. 5C, in a state before the first substrate 110 and the second substrate 120 are bonded to each other, the gates of the transistors connected to the connection portions CN12, CN13, CN15, and CN17 are also connected to the drain of the other transistor. That is, the gates of the n-channel transistors MN3 and MN4 and the p-channel transistors MP1, MP2, MP3, and MP4 are not in a floating state. Therefore, it is possible to suppress the introduction of plasma-induced damage to the gate insulating film in the manufacturing process of each of the first substrate 110 and the second substrate 120, and to improve the manufacturing yield.

The circuit configurations of the voltage conversion circuit 22 and the inverters 24 and 26 and the configuration of the connection portions between the first substrate 110 and the second substrate 120 are not necessarily limited to the examples of FIG. 5B and FIG. 5C. In addition, the influence of plasma induced damage may be reduced depending on the manufacturing process of the first substrate 110 or the second substrate 120, and the above description does not positively exclude the application of the configuration example of FIG. 5B.

Here, the pixel vertical scanning circuit 20 and the memory vertical scanning circuit 40 are exemplified, and the configuration in which the n-channel transistors and the p-channel transistors are arranged on different semiconductor substrates has been described, but the same configuration may be applied to other peripheral circuits configured by CMOS circuits.

By arranging the n-channel transistors and the p-channel transistors constituting the CMOS circuit on different semiconductor substrates, it is possible to prevent a p-n junction from being formed between a p-type well on which the n-channel transistors are arranged and an n-type well on which the p-channel transistors are arranged. Accordingly, it is possible to prevent a parasitic thyristor element from being formed, and it is possible to improve resistance to latch-up due to noise or the like.

Further, when the n-channel transistors and the p-channel transistors are arranged on the same semiconductor substrate, a physical space for electrically separating the p-type well in which the n-channel transistors are arranged and the n-type well in which the p-channel transistors are arranged is required, which may be an obstacle to miniaturization. However, in the configuration of the present embodiment, since the n-channel transistors and the p-channel transistors are formed in separate semiconductor substrates physically separated from each other, it is not necessary to provide a space for separating the wells, and the layout area of the peripheral circuit may be reduced.

According to the above configuration, the power supply line and the ground line may be arranged on different semiconductor substrates, for example, like the power supply voltage line of the voltage SVDD and the ground voltage line of the voltage SGND in FIG. 5B and FIG. 5C. Therefore, it is not necessary to arrange the power supply line and the ground line in parallel in terms of layout, whereby it is possible to reduce a short circuit defect between the power supply line and the ground line.

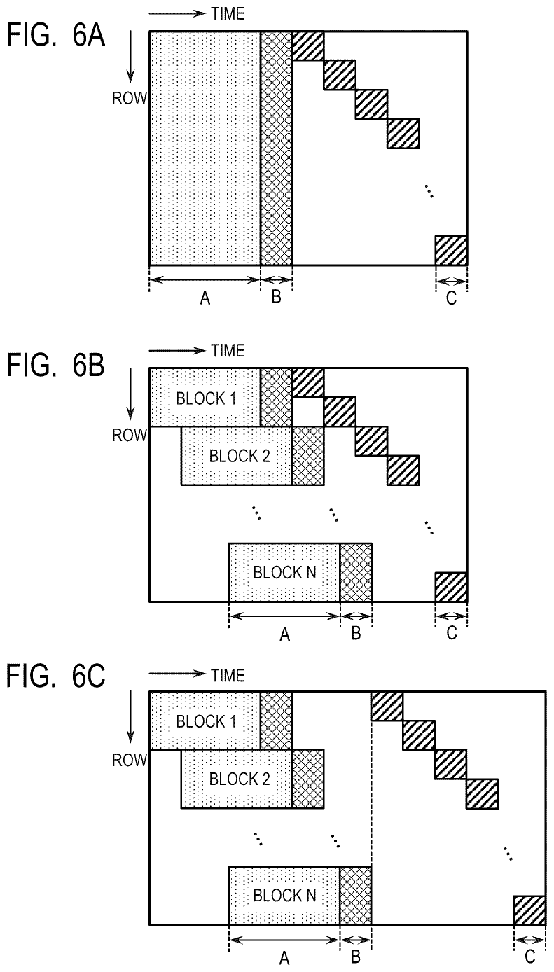

Next, the operation of the photoelectric conversion device according to the present embodiment will be described with reference to FIG. 6A to FIG. 10.

FIG. 6A to FIG. 6C are schematic diagrams illustrating scanning images in the row scanning direction with respect to time. In FIG. 6A to FIG. 6C, the vertical direction indicates the row scanning direction, and the horizontal direction indicates the time. The period A in which the dotted pattern is added is an exposure period of the pixel 12. The period B in which the cross-hatched pattern is added is a pixel memory write period in which a signal of the pixel 12 is read out and written into the pixel memory 32. The period C in which the hatched pattern with diagonal lines downward to the left is added is a pixel memory readout period in which a signal of the pixel memory 32 is read out to the signal processing circuit 52. The drive patterns of FIG. 6A to FIG. 6C are examples, and the drive patterns of the photoelectric conversion device according to the present embodiment are not limited thereto.

In the driving pattern of FIG. 6A, an operation of simultaneously performing the shutter operation for defining the start and the end of the period A in all the pixels 12, that is, a so-called global shutter operation is performed. The period B is also performed in all the pixels 12 and the pixel memory 32 at the same time. The period C is sequentially performed row by row and performed column by column in each row.

The plurality of rows included in the pixel unit 10 and the memory unit 30 may be divided into a plurality of blocks (N-number of blocks) each including two or more rows, and the period A and the period B may be performed in block units.

FIG. 6B and FIG. 6C are driving patterns in which the period A and the period B are executed while sequentially shifting the start time in units of blocks. That is, in the blocks 1, 2, . . . , and N, the start times of the period A and the period B are sequentially delayed by the length of the period C (one horizontal period). The period C is sequentially performed on a row-by-row basis and on a column-by-column basis in each row as in the driving pattern of FIG. 6A.

The driving pattern of FIG. 6B and the driving pattern of FIG. 6C are different in the start timing of the period C. That is, in the driving pattern of FIG. 6B, the period C of each row is sequentially executed after the period A and the period B of the block 1 are ended. On the other hand, in the driving pattern of FIG. 6C, the period C of each row is sequentially executed after the period A and the period B of all the blocks are ended.

The transfer operation of the pixel signal from the pixel unit 10 to the memory unit 30 in block units may be controlled by the control signal SEL of the select transistor M4 and the control signal BLK of the current source switch transistor M11 in the circuit diagram of FIG. 4.

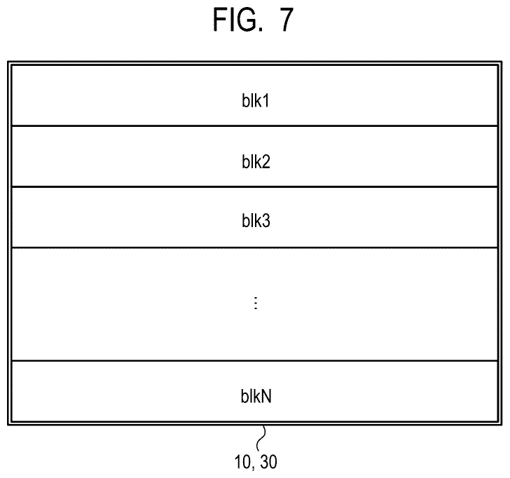

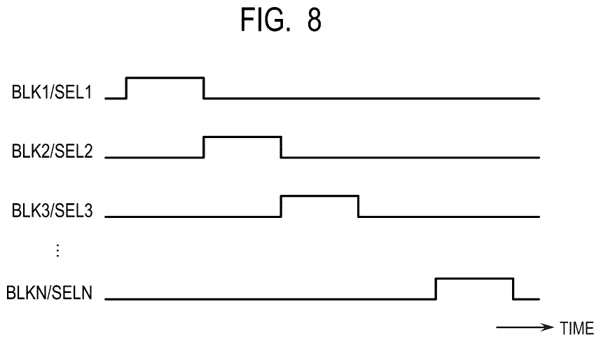

For example, it is assumed that the pixel unit 10 and the memory unit 30 are divided into a plurality of (N-number of) blocks blk1, blk2, blk3, . . . , and blkN in units of rows as illustrated in FIG. 7. It is also assumed that the control signals of the select transistors M4 of the pixels 12 belonging to the blocks blk1, blk2, blk3, . . . , and blkN are referred to as control signals SEL1, SEL2, SEL3, . . . , and SELN, respectively. It is also assumed that the control signals of the current source switch transistors M11 of the pixel memories 32 belonging to the blocks blk1, blk2, blk3, . . . , blkN are referred to as control signals BLK1, BLK2, BLK3, . . . , BLKN, respectively. In this case, as illustrated in, e.g., FIG. 8, the pixel 12 and the pixel memory 32 may be sequentially driven so that the control signals SEL1 and BLK1, the control signals SEL2 and BLK2, the control signals SEL3 and BLK3, . . . , and the control signals SELN and BLKN may be sequentially asserted.

Next, writing operation to the pixel memory 32 in the period B is explained with reference to FIG. 9. FIG. 9 is a timing chart illustrating a writing operation to the pixel memory. FIG. 9 illustrates waveforms of the control signals RES, TXA, TXB, SEL, BLK, RESC, SWN, SWA and SWAB and the voltage VREADP of the node VREADP. In FIG. 9, a period just before time t1 is a charge accumulation period (period A) in the photoelectric conversion elements PDA and PDB, and a period from the time t1 to time t10 is a writing period (period B) in the pixel memory 32.

Just before the time t1, the control signal RES is at high-level, and the reset transistor M2 of the pixel 12 is in the on state. Thus, the node FD of the pixel 12 is set (reset) to a voltage corresponding to the voltage SVDD. In addition, the control signal RESC is at high-level, and the reset transistor M17 of the pixel memory 32 is in the on state. Thus, the voltage of the node VREADP is set to a voltage corresponding to the voltage MVDD. The control signals SWN, SWA, and AWAB are at high-level, and the sampling transistors M14, M15, and M16 are in the on state. As a result, one end of each of the hold capacitors CN, CA, and CAB is set to a voltage corresponding to the voltage MVDD. Note that the control signals TXA, TXB, SEL, and BLK are at low-level just before the time t1.

At the time t1, the memory vertical scanning circuit 40 controls the control signals RESC, SWN, SWA, and AWAB from high-level to low-level. Accordingly, the reset transistor M17 and the sampling transistors M14, M15, and M16 of the pixel memory 32 are turned off, and the hold capacitors CN, CA, and CAB are in a state where the voltage set just before the time t1 is held.

Also at the time t1, the pixel vertical scanning circuit 20 controls the control signal SEL from low-level to high-level. Further, the memory vertical scanning circuit 40 controls the control signal BLK from low-level to high-level. As a result, the select transistor M4 and the current source switch transistor M11 are turned on, a bias current is supplied to the amplifier transistor M3 of the pixel 12, and a signal corresponding to the voltage of the node FD is output to the signal output line 16.

At the subsequent time t2, the pixel vertical scanning circuit 20 controls the control signal RES from high-level to low-level. As a result, the reset transistor M2 is turned off, and the node FD holds the reset state at the voltage SVDD. The voltage of the node FD, which is settled after the reset transistor M2 is turned off, is the reset voltage of the node FD. A voltage (a noise signal voltage (hereinafter referred to as an N-signal)) corresponding to the reset voltage of the node FD is output to the node VREADP via the signal output line 16 and the connection portion CN11.

Also at the time t2, the memory vertical scanning circuit 40 controls the control signal SWN from low-level to high-level. As a result, the sampling transistor M14 is turned on, and the hold capacitor CN is connected to the node VREADP, whereby the hold capacitor CN becomes a state into which a signal corresponding to the voltage of the node VREADP may be written.

At the subsequent time t3, the memory vertical scanning circuit 40 controls the control signal SWN from high-level to low-level. As a result, the sampling transistor M14 is turned off, and the N-signal output to the node VREADP is held in the hold capacitor CN.

At the subsequent time t4, the pixel vertical scanning circuit 20 controls the control signal TXA from low-level to high-level. As a result, the transfer transistor M1A is turned on, and the charge held in the photoelectric conversion element PDA is transferred to the node FD. The node FD has a voltage corresponding to the amount of charge transferred from the photoelectric conversion element PDA.

At the subsequent time t5, the pixel vertical scanning circuit 20 controls the control signal TXA from high-level to low-level. As a result, the transfer transistor M1A is turned off. A voltage corresponding to the amount of charge transferred from the photoelectric conversion element PDA is output to the node VREADP via the signal output line 16 and the connection portion CN11. The voltage output to the node VREADP after the transfer transistor M1A is turned off and the voltage of the node FD is settled is the first image signal voltage (hereinafter, referred to as an SA-signal).

Also at the time t5, the memory vertical scanning circuit 40 controls the control signal SWA from low-level to high-level. As a result, the sampling transistor M15 is turned on, and the hold capacitor CA is connected to the node VREADP, whereby the hold capacitor CA becomes a state into which a signal corresponding to the voltage of the node VREADP may be written.

At the subsequent time t6, the memory vertical scanning circuit 40 controls the control signal SWA from high-level to low-level. As a result, the sampling transistor M15 is turned off, and the SA-signal output to the node VREADP is held in the hold capacitor CA.

At the subsequent time t7, the pixel vertical scanning circuit 20 controls the control signals TXA and TXB from low-level to high-level. As a result, the transfer transistors M1A and M1B are turned on, and the charges held in the photoelectric conversion elements PDA and PDB are transferred to the node FD. That is, in the node FD, the charge of the photoelectric conversion element PDA and the charge of the photoelectric conversion element PDB are added. The node FD has a voltage corresponding to the amount of charge transferred from the photoelectric conversion elements PDA and PDB.

At the subsequent time t8, the pixel vertical scanning circuit 20 controls the control signals TXA and TXB from high-level to low-level. As a result, the transfer transistors M1A and M1B are turned off. A voltage corresponding to the amount of charge transferred from the photoelectric conversion elements PDA and PDB is output to the node VREADP via the signal output line 16 and the connection portion CN11. The voltage output to the node VREADP after the transfer transistors M1A and M1B are turned off and the voltage of the node FD is settled is the second image signal voltage (hereinafter referred to as SAB-signal).

At the subsequent time t9, the memory vertical scanning circuit 40 controls the control signal SWAB from low-level to high-level. As a result, the sampling transistor M16 is turned on, and the hold capacitor CAB is connected to the node VREADP, whereby the hold capacitor CAB becomes a state into which a signal corresponding to the voltage of the node VREADP may be written.

At the subsequent time t10, the memory vertical scanning circuit 40 controls the control signal SWAB from high-level to low-level. As a result, the sampling transistor M16 is turned off, and the SAB-signal output to the node VREADP is held in the hold capacitor CAB.

In this manner, the N-signal, the SA-signal, and the SAB-signal of each pixel 12 may be held in the hold capacitors CN, CA, and CAB of the pixel memory 32.

Next, a readout operation from the pixel memory 32 to the signal processing circuit 52 in the period C will be described with reference to FIG. 10. FIG. 10 is a timing chart illustrating a readout operation from the pixel memory 32 to the signal processing circuit 52. FIG. 10 illustrates waveforms of the control signals SELM(N), SELM(N+1), BLKM, RESC, SWN, SWA and SWAB. In FIG. 10, a period just before time t21 is a writing period (period B) to the pixel memory 32, and a period from the time t21 to time t30 is a pixel memory readout period (period C) for one row. FIG. 10 illustrates a pixel memory readout period for two rows (N-th row and (N+1)-th row).

Just before the time t21, the control signal RESC is at low-level, and the reset transistor M17 of the pixel memory 32 is in the off state. The control signals SWN, SWA, and AWAB are at low-level, and the sampling transistors M14, M15, and M16 are in the off state. The control signals SELM(N) and SELM(N+1) are at low-level, and the select transistors M19 of the pixel memories 32 in the N-th row and the (N+1)-th row are in the off state. Further, the control signal BLKM is at low-level, and the current source switch transistor M21 is in the off state.

At the time t21, the memory vertical scanning circuit 40 controls the control signal SELM(N) of the N-th row from low-level to high-level. Further, the column control circuit 80 controls the control signal BLKM supplied to the signal processing circuit of each column from low-level to high-level. As a result, the select transistors M19 of the corresponding row and the current source switch transistors M21 of each column are turned on, a bias current is supplied to the amplifier transistor M18 of each of the pixel memories 32 of the corresponding row, and a signal corresponding to the voltage of the node VREADP is output to each of the signal output lines 36.

In the subsequent period from the time t21 to time t22, the memory vertical scanning circuit 40 controls the control signal RESC of the N-th row from low-level to high-level. As a result, the reset transistor M17 of each of the pixel memories 32 in the N-th row is turned on, and the node VREADP of each of the pixel memories 32 in the N-th row is set to a voltage corresponding to the voltage MVDD.

In the subsequent period from time t23 to time t24, the memory vertical scanning circuit 40 controls the control signal SWN of the N-th row from low-level to high-level. As a result, the sampling transistor M14 of each of the pixel memories 32 in the N-th row is turned on, and the N-signal held in the hold capacitor CN is output to the node VREADP. A voltage corresponding to the N-signal is output to the node VLOUT via the signal output line 36 and the connection portion CN21.

The reason why the node VREADP is set to a voltage corresponding to the voltage MVDD before the N-signal is read out to the node VREADP is to prevent the readout signal from being affected by the state of the node VREADP before the signal is read out. The reason why the node VREADP is set to the voltage corresponding to the voltage MVDD in the period from time t24 to time t25 and the period from time t27 to time t28 described later is the same. Here, the node VREADP is set to a voltage corresponding to the voltage MVDD, but the node VREADP may be set to another power supply voltage.

In the subsequent period from the time t24 to the time t25, the memory vertical scanning circuit 40 controls the control signal RESC of the N-th row from low-level to high-level. As a result, the reset transistor M17 of each of the pixel memories 32 in the N-th row is turned on, and the node VREADP of each of the pixel memories 32 in the N-th row is set to a voltage corresponding to the voltage MVDD again.

In the subsequent period from time t26 to time t27, the memory vertical scanning circuit 40 controls the control signal SWA of the N-th row from low-level to high-level. As a result, the sampling transistor M15 of each of the pixel memories 32 in the N-th row is turned on, and the SA-signal held in the hold capacitor CA is output to the node VREADP. A voltage corresponding to the SA-signal is output to the node VLOUT via the signal output line 36 and the connection portion CN21.

In the subsequent period from the time t27 to the time t28, the memory vertical scanning circuit 40 controls the control signal RESC of the N-th row from low-level to high-level. As a result, the reset transistor M17 of each of the pixel memories 32 in the N-th row is turned on, and the node VREADP of each of the pixel memories 32 in the N-th row is set to a voltage corresponding to the voltage MVDD again.

In the subsequent period from time t29 to time t30, the memory vertical scanning circuit 40 controls the control signal SWAB of the N-th row from low-level to high-level. As a result, the sampling transistor M16 of each of the pixel memories 32 in the N-th row is turned on, and the SAB signal held in the hold capacitor CAB is output to the node VREADP. A voltage corresponding to the SAB signal is output to the node VLOUT via the signal output line 36 and the connection portion CN21.

At the subsequent time t30, the memory vertical scanning circuit 40 controls the control signal SELM(N) of the N-th row from high-level to low-level. Thus, the readout of the signals from the pixel memories 32 in the N-th row is completed.

After the subsequent time t31, in the same manner as in the period from the time t21 to the time t30, readout of the signals from the pixel memories 32 of the (N+1)-th row is executed. The same applies to the readout of signals from the pixel memories 32 of the other rows. The control signal BLKM is controlled from high-level to low-level at a timing when readout of the signals from the pixel memories 32 of all rows is completed.

In this manner, the N-signal, the SA-signal, and the SAB-signal of all the pixels 12 held in the memory unit 30 may be read out to the signal processing unit 50 of each column in units of rows.

Although the driving example in which the SA-signal and the SAB-signal are read out from the pixel 12 as the signals based on the charge of the photoelectric conversion elements PDA and PDB is described here, the signals read out from the pixel 12 are not limited thereto. For example, a driving in which the transfer transistors M1A and M1B are simultaneously driven to read out a signal based on the charge read out to the node FD or a driving in which an SA-signal based on the charge of the photoelectric conversion element PDA and an SB-signal based on the charge of the photoelectric conversion element PDB are read out may be applied.

As described above, in the present embodiment, in the photoelectric conversion device configured by the plurality of substrates, the peripheral circuit is configured by a circuit including a complementary connection between a transistor of a first conductivity type provided on a first substrate and a transistor of a second conductivity type provided on a second substrate. Therefore, according to the present embodiment, in each of the first substrate and the second substrate, it is possible to prevent a p-n junction from being formed between a p-type well in which the n-channel transistor is arranged and an n-type well in which the p-channel transistor is arranged. Accordingly, it is possible to prevent the parasitic thyristor element from being formed, and it is possible to improve resistance to latch-up due to noise or the like. Further, since it is not necessary to provide a space for separating the wells, the layout area of the peripheral circuit may be reduced. Therefore, according to the present embodiment, in the photoelectric conversion device including the plurality of substrates, it is possible to improve the performance of the peripheral circuit, and it is possible to realize the improvement of the signal quality and the cost reduction.

### Second Embodiment

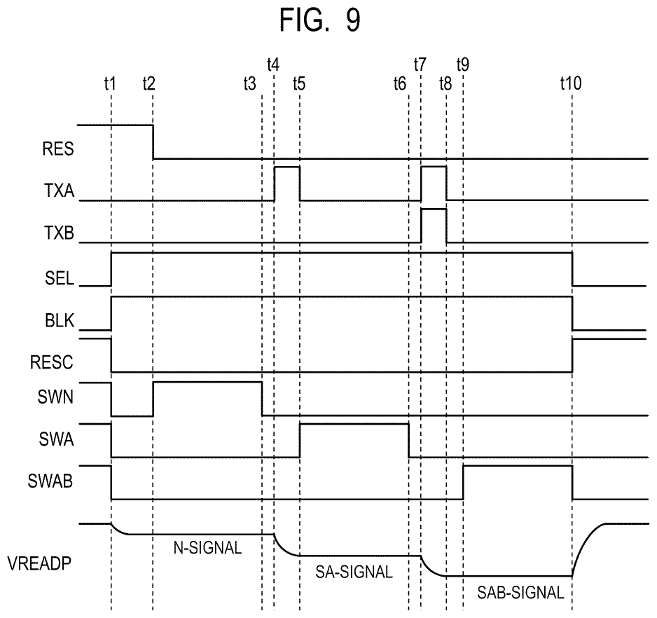

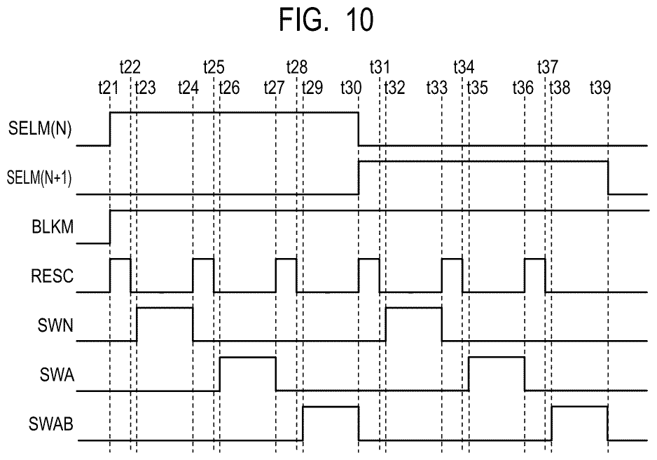

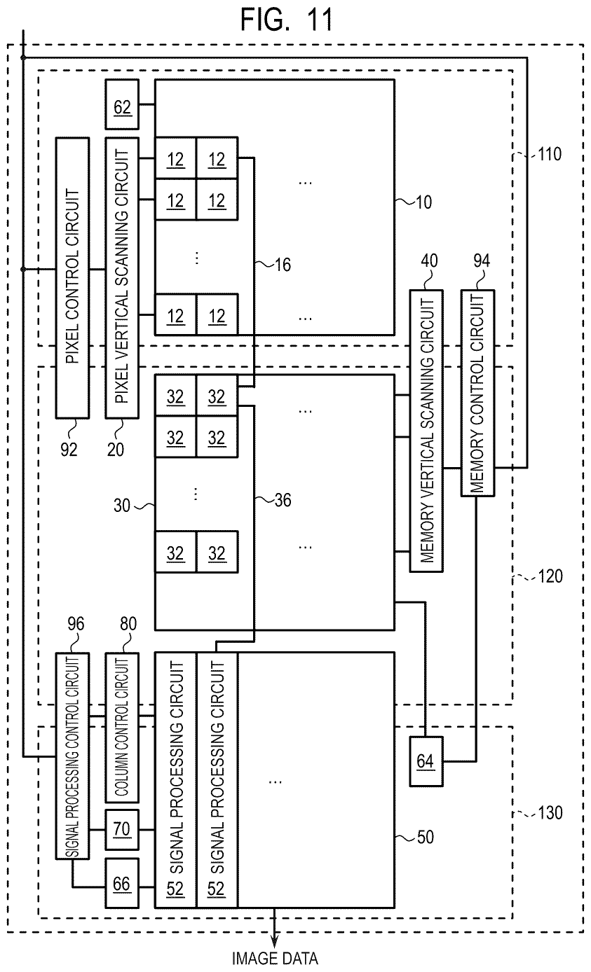

A photoelectric conversion device according to a second embodiment will be described with reference to FIG. 11 to FIG. 15. The same components as those of the photoelectric conversion device according to the first embodiment are denoted by the same reference numerals, and description thereof will be omitted or simplified.

Allocation of each functional block to each substrate in the photoelectric conversion device according to the present embodiment will be described with reference to FIG. 11. FIG. 11 is a schematic diagram illustrating allocation of each functional block to each substrate in the photoelectric conversion device according to the present embodiment.

Similarly to the first embodiment, the photoelectric conversion device according to the present embodiment is configured by stacking three substrates of the first substrate 110, the second substrate 120, and the third substrate 130. Among the functional blocks described above, the pixel unit 10, a part of the pixel vertical scanning circuit 20, a part of the pixel control circuit 92, a part of the memory vertical scanning circuit 40, a part of the memory control circuit 94, and the bias generation circuit 62 are arranged on the first substrate 110. Among the functional blocks described above, the memory unit 30, another part of the pixel vertical scanning circuit 20, another part of the pixel control circuit 92, another part of the memory vertical scanning circuit 40, and another part of the memory control circuit 94 are arranged on the second substrate 120. A part of the signal processing unit 50, a part of the column control circuit 80, and a part of the signal processing control circuit 96 are further arranged on the second substrate 120. Among the functional blocks described above, another part of the signal processing unit 50, another part of the column control circuit 80, another part of the signal processing control circuit 96, the bias generation circuits 64 and 66, and the reference signal output circuit 70 are arranged on the third substrate 130.

In the first embodiment, the pixel vertical scanning circuit 20 and the memory vertical scanning circuit 40 are provided over the first substrate 110 and the second substrate 120. In contrast, in the present embodiment, the pixel vertical scanning circuit 20, the pixel control circuit 92, the memory vertical scanning circuit 40, and the memory control circuit 94 are provided over the first substrate 110 and the second substrate 120. Further, in the present embodiment, the signal processing unit 50, the column control circuit 80, and the signal processing control circuit 96 are provided over the second substrate 120 and the third substrate 130.

More specifically, the n-channel transistors of the circuits constituting the pixel unit 10, the pixel vertical scanning circuit 20, the pixel control circuit 92, the memory unit 30, the memory vertical scanning circuit 40, the bias generation circuit 62, and the memory control circuit 94 are arranged on the first substrate 110. The p-channel transistors of the circuits constituting the pixel unit 10, the pixel vertical scanning circuit 20, the pixel control circuit 92, the memory unit 30, the memory vertical scanning circuit 40, and the memory control circuit 94 are arranged on the second substrate 120. The p-channel transistors of the circuits constituting the signal processing unit 50, the column control circuit 80, the signal processing control circuit 96, and the reference signal output circuit 70 are disposed on the second substrate 120. The n-channel transistors of the circuits constituting the signal processing unit 50, the bias generation circuits 64 and 66, the column control circuit 80, the signal processing control circuit 96, and the reference signal output circuit 70 are arranged on the third substrate 130. When the photoelectric conversion device is divided into two semiconductor substrates, the n-channel transistors among the transistors constituting each functional block may be arranged on the first semiconductor substrate, and the p-channel transistors among the transistors constituting each functional block may be arranged on the second semiconductor substrate.

By arranging the n-channel transistors and the p-channel transistors constituting each functional block on different semiconductor substrates, it is possible to prevent a parasitic thyristor element from being formed as described above, and it is possible to improve resistance to latch-up due to noise or the like. In addition, a physical space for electrically separating a p-type well and an n-type well from each other becomes unnecessary, and the layout area may be reduced. In addition, it is not necessary to arrange the power supply line and the ground line in parallel in terms of layout, and it is possible to reduce a short circuit defect between the power supply line and the ground line.

In addition, by using one of an n-channel transistor and a p-channel transistor as transistors arranged in each semiconductor substrate, the number of manufacturing steps of each semiconductor substrate may be reduced, and as a result, the manufacturing cost of the photoelectric conversion device may be reduced.

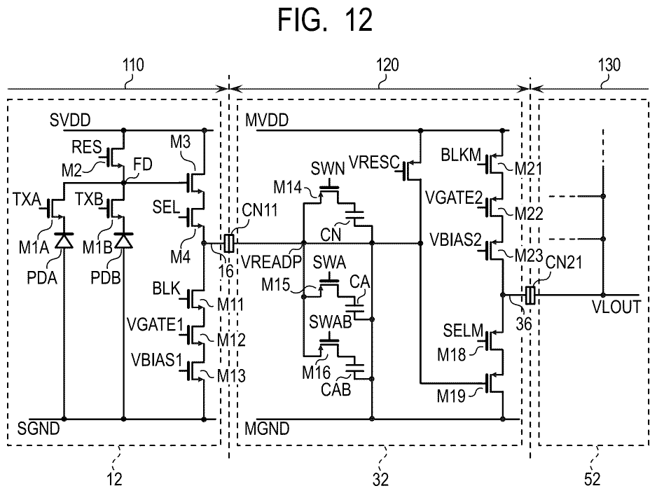

Next, the circuit configuration of the pixel 12 and the pixel memory 32 in the photoelectric conversion device according to the present embodiment will be described more specifically with reference to FIG. 12. FIG. 12 is an equivalent circuit diagram illustrating a configuration example of the pixel 12 and the pixel memory 32 in the photoelectric conversion device according to the present embodiment.

On the first substrate 110, the n-channel transistors are arranged among transistors constituting each functional block. In the case of the pixel 12 using electrons as the signal charge, as described above, the pixel circuit may be configured using the n-channel transistors. Therefore, the circuit configuration of the pixel unit 10 arranged on the first substrate 110 may be the same as that of the first embodiment. In the first embodiment, the current source circuit (the current source switch transistor M11, the cascode transistor M12, and the pixel current source transistor M13) for supplying the bias current to the amplifier transistor M3 is formed of the n-channel transistors on the second substrate 120. Therefore, in the present embodiment, these n-channel transistors are transferred from the second substrate 120 to the first substrate 110.

On the second substrate 120, the p-channel transistors are arranged among transistors constituting each functional block. Therefore, in the present embodiment, the sampling transistors M14, M15, and M16, the reset transistor M17, and the amplifier transistor M18 are configured using the p-channel transistors. Further, a current source circuit (the current source switch transistor M21, the cascode transistor M22, and the pixel memory current source transistor M23) for supplying a bias current to the amplifier transistor M18 is formed of the p-channel transistors and is transferred to the second substrate 120.

The amplifier transistor M3 outputs a pixel signal corresponding to the voltage of the node FD to the pixel memory 32 via the select transistor M4. The pixel signal output to the pixel memory 32 is written to the hold capacitors CN, CA, and CAB via the sampling transistors M14, M15, and M16. The amplifier transistor M18 outputs a pixel signal corresponding to the voltage of the node VREADP from which the pixel signal written in the hold capacitors CN, CA, and CAB is read out, to the signal processing circuit 52 via the select transistor M19. That is, the pixel 12 and the pixel memory 32 output the output of the two-stage source follower circuit including the source follower circuit with the signal of the node FD as an input and the source follower circuit with the signal of the node VREADP as an input to the signal processing circuit 52 (node VLOUT).

In general, the transfer function of the two-stage source follower circuit is expressed by the following Expression (1).

Vout=Vin−ΔV1−ΔV2 (1)

Where Vin is the input voltage and Vout is the output voltage. ΔV1 is the sum of an overdrive voltage and a threshold voltage of the input transistor of the source follower circuit of the first stage, and ΔV2 is the sum of an overdrive voltage and a threshold voltage of the input transistor of the source follower circuit of the second stage.

As can be seen from the Expression (1), since the output voltage Vout is shifted to the low voltage side by (ΔV1+ΔV2) with respect to the input voltage Vin, the input/output possible range of the entire source follower circuit is greatly reduced.

In this regard, in the circuit configuration of the present embodiment illustrated in FIG. 12, by making the conductivity type of the amplifier transistor M3 and the conductivity type of the amplifier transistor M18 opposite to each other, it is possible to perform an operation of cancelling the shift of ΔV1 by the shift of ΔV2. Therefore, according to the present embodiment, it is possible to widen the input/output range of the entire circuit as compared with a case where a two-stage source follower circuit configured by the transistors of the same conductivity type is configured.

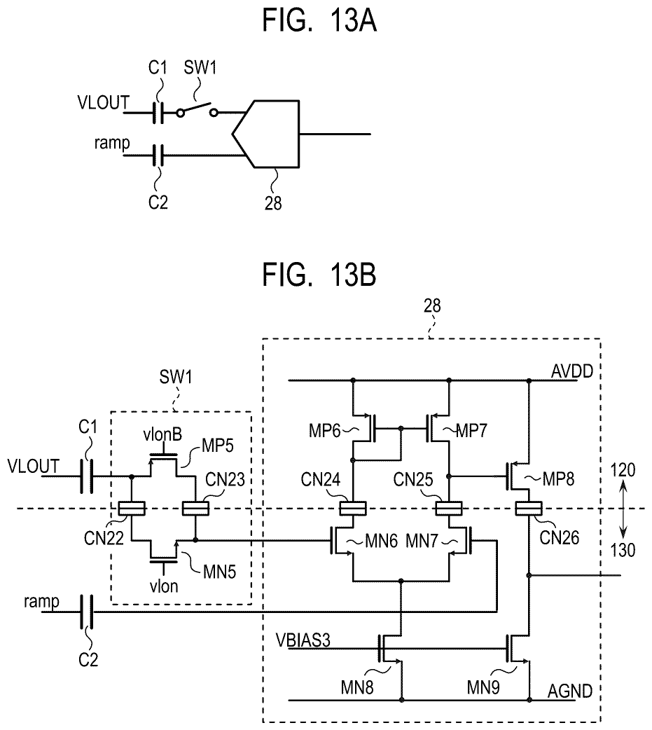

Next, a configuration example of the signal processing circuit 52 in the photoelectric conversion device according to the present embodiment will be described more specifically with reference to FIG. 13A and FIG. 13B. FIG. 13A and FIG. 13B are circuit diagrams illustrating a part of the signal processing circuit 52 in the photoelectric conversion device according to the present embodiment. FIG. 13A and FIG. 13B are circuit diagrams of a comparator circuit 28 constituting a ramp-type AD conversion circuit and an input portion thereof as an example of a circuit constituting the signal processing circuit 52. FIG. 13A is an equivalent circuit diagram, and FIG. 13B is an example of a circuit diagram in which FIG. 13A is rewritten with transistor-level elements.

The ramp-type AD conversion circuit converts the pixel signal from an analog signal to a digital signal based on a result of comparison between the pixel signal (voltage of the node VLOUT) output from the pixel memory 32 and the reference signal ramp output from the reference signal output circuit 70. Specifically, the ramp-type AD conversion circuit outputs, as a digital value of the pixel signal, a count value corresponding to the length of a period from the start of the comparison operation between the pixel signal and the reference signal ramp to the inversion of the output signal that is the result of the comparison.

As illustrated in, e.g., FIG. 13A, the pixel signal (the voltage of the node VLOUT) is input to one of the input terminals of the comparator circuit 28 via an input capacitor C1 and a switch SW1. The reference signal ramp is input to the other of the input terminals of the comparator circuit 28 via an input capacitor C2. The comparator circuit 28 compares the level of the pixel signal with the level of the reference signal ramp, and outputs a signal corresponding to the comparison result. For example, the comparator circuit 28 outputs a high-level signal when the level of the reference signal ramp is lower than the level of the pixel signal. When the level of the reference signal ramp is higher than the level of the pixel signal, the comparator circuit 28 outputs a low-level signal. The relationship between the magnitude of the input signal and the level of the output signal may be reversed.

As illustrated in, e.g., FIG. 13B, the input capacitor C1 may be provided on the second substrate 120. One terminal of the input capacitor C1 is connected to the signal output line 36 (node VLOUT). The input capacitor C2 may be provided on the third substrate 130. The reference signal ramp output from the reference signal output circuit 70 is input to one terminal of the input capacitor C2.

As illustrated in, e.g., FIG. 13B, the switch SW1 may include a p-channel transistor MP5 provided on the second substrate 120 and an n-channel transistor MN5 provided on the third substrate 130. A source of the p-channel transistor MP5 is connected to the other terminal of the input capacitor C1. A connection node between the other terminal of the input capacitor C1 and the source of the p-channel transistor MP5 is connected to a drain of the n-channel transistor MN5 via a connection portion CN22, which is one of the electrical connection portions between the second substrate 120 and the third substrate 130. A drain of the p-channel transistor MP5 is connected to a source of the n-channel transistor MN5 via a connection portion CN23, which is one of the electrical connection portions between the second substrate 120 and the third substrate 130. A control signal vlon is input to a gate of the n-channel transistor MN5. A control signal vlonB, which is an inverted signal of the control signal vlon, is input to a gate of the p-channel transistor MP5.

As illustrated in, e.g., FIG. 13B, the comparator circuit 28 may include p-channel transistors MP6, MP7, and MP8 provided on the second substrate 120 and n-channel transistors MN6, MN7, MN8, and MN9 provided on the third substrate 130. Sources of the p-channel transistors MP6, MP7, and MP8 are connected to the power supply voltage node (voltage AVDD). Gates of the p-channel transistors MP6 and MP7 and a drain of the p-channel transistor MP6 are connected to a drain of the n-channel transistor MN6 via a connection portion CN24, which is one of the electrical connection portions between the second substrate 120 and the third substrate 130. A drain of the p-channel transistor MP7 is connected to a drain of the n-channel transistor MN7 via a connection portion CN25, which is one of the electrical connection portions between the second substrate 120 and the third substrate 130. Sources of the n-channel transistors MN6 and MN7 are connected to a drain of the n-channel transistor MN8. A drain of the p-channel transistor MP7 is connected to a gate of the p-channel transistor MP8. A drain of the p-channel transistor MP8 is connected to a drain of the n-channel transistor MN9 via a connection portion CN26, which is one of the electrical connection portions between the second substrate 120 and the third substrate 130. Sources of the n-channel transistors MN8 and MN9 are connected to the ground voltage node (voltage AGND).

A gate of the n-channel transistor MN6 is one input terminal of the comparator circuit 28 and is connected to a connection node between the source of the n-channel transistor MN5 of the switch SW1 and the connection portion CN23. A gate of the n-channel transistor MN7 is the other input terminal of the comparator circuit 28 and is connected to the other terminal of the input capacitor C2. A voltage VBIAS3 from the bias generation circuit 66 is input to gates of the n-channel transistors MN8 and MN9 as tail current sources. A connection node between the drain of the n-channel transistor MN9 and the connection portion CN26 serves as an output terminal of the comparator circuit 28.

As described above, in the present embodiment, the switch SW1 is configured by a complementary switch circuit including the p-channel transistor MP5 arranged on the second substrate 120 and the n-channel transistor MN5 arranged on the third substrate 130. By configuring the switch SW1 in this manner, it is possible to reduce the on-resistance in the case where the input voltage is low as compared with the case where the switch SW1 is configured only by the p-channel transistor arranged on the second substrate 120, and it is possible to expand the operation range and reduce the power consumption. The same effect may also be obtained when the switch SW1 is configured only by the n-channel transistor arranged on the third substrate 130.

Further, in the present embodiment, the comparator circuit 28 also includes p-channel transistors MP6, MP7, and MP8 arranged on the second substrate 120 and n-channel transistors MN6, MN7, MN8, and MN9 arranged on the third substrate 130. Thus, a CMOS circuit in which an n-channel transistor and a p-channel transistor are complementarily combined may be formed, and a circuit that cannot be formed only by the p-channel transistor of the second substrate 120 may be formed, so that the degree of freedom in circuit design may be improved.

Other peripheral circuits, such as the pixel control circuit 92, the memory control circuit 94, the signal processing control circuit 96, and the column control circuit 80, may be configured by a combination of logic circuits. The logic circuits constituting these circuits may include a NAND circuit and a NOR circuit, and the NAND circuit and the NOR circuit may also be configured by complementarily combining transistors having different conductivity types as in the case of the switch SW1 and the comparator circuit 28 described above.

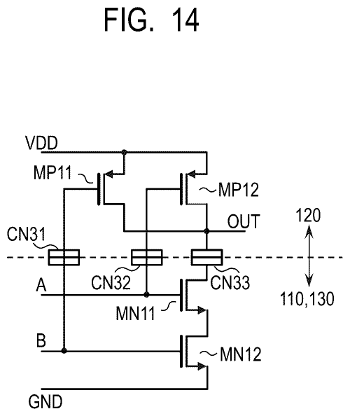

FIG. 14 is a circuit diagram illustrating a configuration example of a NAND circuit. As illustrated in, e.g., FIG. 14, a two-input NAND circuit may include p-channel transistors MP11 and MP12 arranged on the second substrate 120 and n-channel transistors MN11 and MN12 arranged on the first substrate 110 or the third substrate 130. Sources of the p-channel transistors MP11 and MP12 are connected to the power supply voltage node (voltage VDD). Drains of the p-channel transistors MP11 and MP12 are connected to a drain of the n-channel transistor MN11 via a connection portion CN33, which is one of the electrical connection portions between the second substrate 120 and the first substrate 110 or the third substrate 130. A source of the n-channel transistor MN11 is connected to a drain of the n-channel transistor MN12. A source of the n-channel transistor MN12 is connected to the ground voltage node (voltage GND). A gate of the p-channel transistor MP11 is connected to a gate of the n-channel transistor MN12 via a connection portion CN31, which is one of the electrical connection portions between the second substrate 120 and the first substrate 110 or the third substrate 130. A gate of the p-channel transistor MP12 is connected to a gate of the n-channel transistor MN11 via a connection portion CN32, which is one of the electrical connection portions between the second substrate 120 and the first substrate 110 or the third substrate 130. A connection node between the gate of the n-channel transistor MN11 and the gate of the p-channel transistor MP12 serves as one input A, and a connection node between the gate of the n-channel transistor MN12 and the gate of the p-channel transistor MP11 serves as the other input B. A connection node between the drains of the p-channel transistors MP11 and MP2 and the drain of the n-channel transistor MN11 serves as an output OUT.

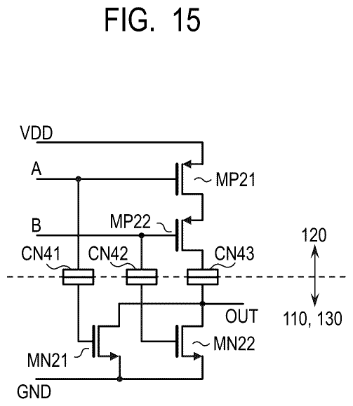

FIG. 15 is a circuit diagram illustrating a configuration example of a NOR circuit. As illustrated in, e.g., FIG. 15, a two-input NOR circuit may include p-channel transistors MP21 and MP22 arranged on the second substrate 120 and n-channel transistors MN21 and MN22 arranged on the first substrate 110 or the third substrate 130. A source of the p-channel transistor MP21 is connected to the power supply voltage node (voltage VDD). A drain of the p-channel transistor MP21 is connected to a source of the p-channel transistor MP22. A drain of the p-channel transistor MP22 is connected to drains of the n-channel transistors MN21 and MN22 via a connection portion CN43, which is one of the electrical connection portions between the second substrate 120 and the first substrate 110 or the third substrate 130. Sources of the n-channel transistors MN21 and MN22 are connected to the ground voltage node (voltage GND). A gate of the p-channel transistor MP21 is connected to a gate of the n-channel transistor MN21 via a connection portion CN41, which is one of the electrical connection portions between the second substrate 120 and the first substrate 110 or the third substrate 130. A gate of the p-channel transistor MP22 is connected to a gate of the n-channel transistor NM22 via a connection portion CN42, which is one of the electrical connection portions between the second substrate 120 and the first substrate 110 or the third substrate 130. A connection node between the gate of the n-channel transistor NM21 and the gate of the p-channel transistor MP21 serves as one input A, and a connection node between the gate of the n-channel transistor MN22 and the gate of the p-channel transistor MP22 serves as the other input B. A connection node between the drain of the p-channel transistor MP22 and the drains of the n-channel transistors MN21 and MN22 serves as an output OUT.

Therefore, peripheral circuits such as the pixel control circuit 92, the memory control circuit 94, the signal processing control circuit 96, and the column control circuit 80 may also be configured by complementarily combining transistors of different conductivity types arranged on different substrates.

As described above, according to the present embodiment, similarly to the first embodiment, in the photoelectric conversion device including the plurality of substrates, it is possible to improve the performance of the peripheral circuit, and it is possible to realize the improvement of the signal quality and the cost reduction. When the conductivity type of the transistors provided in each substrate is one of n-type and p-type, the number of manufacturing steps of each substrate may be reduced and the manufacturing cost may be further reduced.

### Third Embodiment

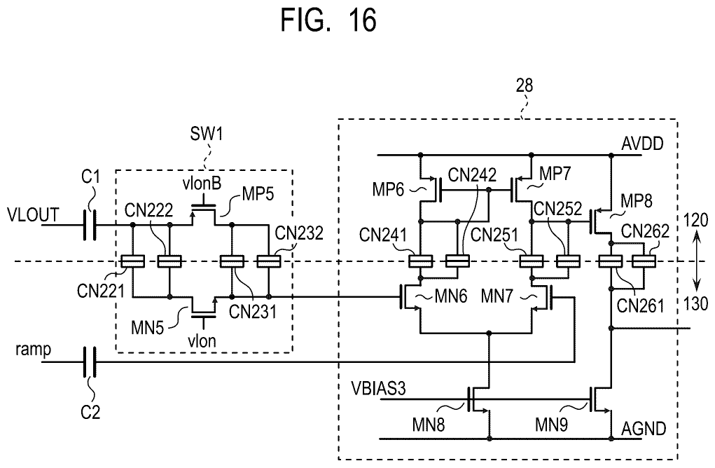

A photoelectric conversion device according to a third embodiment will be described with reference to FIG. 16. The same components as those of the photoelectric conversion device according to the first or second embodiment are denoted by the same reference numerals, and description thereof will be omitted or simplified.

The photoelectric conversion device according to the present embodiment is the same as the photoelectric conversion device according to the first or second embodiment except that the configuration of the connection portions for electrically connecting the semiconductor substrates is different. That is, in the photoelectric conversion device according to the present embodiment, each of the connection portions electrically connecting the semiconductor substrates is configured by a plurality of connection portions arranged in parallel.

FIG. 16 is a circuit diagram in which the configuration of the present embodiment is applied to the signal processing circuit 52 of the photoelectric conversion device according to the second embodiment. That is, in the present embodiment, the connection portion CN22, which connects the source of the p-channel transistor MP5 to the drain of the n-channel transistor MN5, is constituted by two connection portions CN221, CN222, which are arranged in parallel. The connection portion CN23 connecting the drain of the p-channel transistor MP5 to the source of the n-channel transistor MN5 is constituted by two connection portions CN231, CN232 arranged in parallel. The connection portion CN24 connecting the gates of the p-channel transistors MP6 and MP7 and the drain of the p-channel transistor MP6 to the drain of the n-channel transistor MN6 is constituted by two connection portions CN241, CN242 arranged in parallel. The connection portion CN25 connecting the drain of the p-channel transistor MP7 and the gate of the p-channel transistor MP8 to the drain of the n-channel transistor NM7 is constituted by two connection portions CN251, CN252 arranged in parallel. Further, the connection portion CN26 connecting the drain of the p-channel transistor MP8 to the drain of the n-channel transistor MN9 is constituted by two connection portions CN261, CN262 arranged in parallel.

In the configuration example of FIG. 16, each connection portion is configured by two connection portions arranged in parallel, but each connection portion may be configured by three or more connection portions arranged in parallel. In addition, all of the connection portions included in the photoelectric conversion device do not necessarily have to be constituted by a plurality of connection portions arranged in parallel, and a part of the connection portions may be constituted by a plurality of connection portions arranged in parallel. The number of connection portions arranged in parallel may be different for each connection portion.

By configuring the connection portions for electrically connecting the semiconductor substrates by a plurality of connection portions arranged in parallel, the redundancy of the connection portions may be enhanced, and a decrease in yield due to a manufacturing defect of the connection portions may be suppressed. In addition, by making the number of parallel connections in the connection portion connected to the gate of the transistor larger than the number of parallel connections in the other connection portions, the possibility that the gate input becomes unstable due to a defect in the connection portion and a through current flows may be reduced.

As described above, according to the present embodiment, similarly to the first embodiment, in the photoelectric conversion device including the plurality of substrates, it is possible to improve the performance of the peripheral circuit, and it is possible to realize the improvement of the signal quality and the cost reduction. Further, by configuring the connection portions for electrically connecting the semiconductor substrates by a plurality of connection portions arranged in parallel, the redundancy of the connection portions may be enhanced, and a decrease in yield due to a manufacturing defect of the connection portions may be suppressed.

### Fourth Embodiment

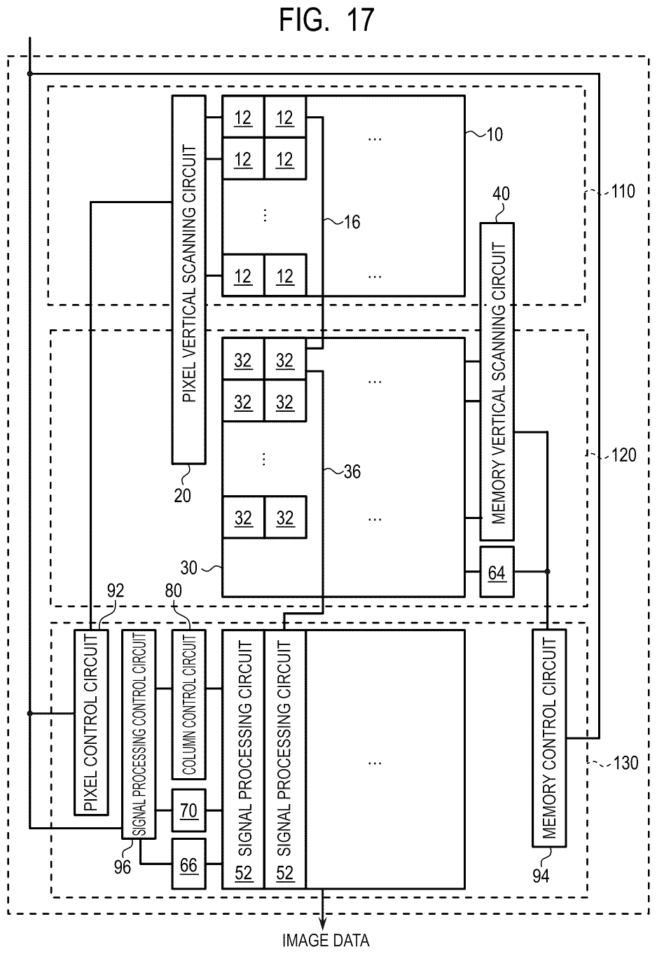

A photoelectric conversion device according to a fourth embodiment will be described with reference to FIG. 17. The same components as those of the photoelectric conversion devices according to the first to third embodiments are denoted by the same reference numerals, and description thereof will be omitted or simplified. FIG. 17 is a schematic diagram illustrating allocation of each functional block to each substrate in the photoelectric conversion device according to the present embodiment.

Similarly to the first to third embodiments, the photoelectric conversion device according to the present embodiment is configured by stacking three substrates of the first substrate 110, the second substrate 120, and the third substrate 130. Among the functional blocks described above, the pixel unit 10, a part of the pixel vertical scanning circuit 20, and a part of the memory vertical scanning circuit 40 are arranged on the first substrate 110. Among the functional blocks described above, the memory unit 30, another part of the pixel vertical scanning circuit 20, another part of the memory vertical scanning circuit 40, and the bias generation circuit 64 are arranged on the second substrate 120. Among the functional blocks described above, the signal processing unit 50, the bias generation circuit 66, the reference signal output circuit 70, the column control circuit 80, the pixel control circuit 92, the memory control circuit 94, and the signal processing control circuit 96 are arranged on the third substrate 130. As described above, in the photoelectric conversion device according to the present embodiment, the pixel control circuit 92 and the memory control circuit 94 are arranged on the same third substrate 130 as the signal processing control circuit 96 and the column control circuit 80.

In general, the withstand voltage of the transistor is mainly determined by a thickness of a gate insulating film, and the thicker the gate insulating film is, the higher the withstand voltage of the transistor is. On the other hand, since the gate capacitance is proportional to the on-state current, the gate insulating film is preferably thin from the viewpoint of the performance of the transistor. Thus, the thickness of the gate insulating film of each transistor is designed to be suitable for characteristics and driving voltage required for each transistor.

For example, among the above-described functional blocks constituting the photoelectric conversion device, the pixel control circuit 92, the memory control circuit 94, the signal processing control circuit 96, and the column control circuit 80 are configured by transistors that operate at a relatively low drive voltage such as 1.8 V. On the other hand, the pixel 12, the pixel memory 32, the signal processing circuit 52, the pixel vertical scanning circuit 20, the memory vertical scanning circuit 40, the bias generation circuits 64 and 66, and the reference signal output circuit 70 are configured by transistors that operate at a relatively high drive voltage such as 3.3 V.

In the first to third embodiments, the pixel control circuit 92 and the memory control circuit 94 are arranged on the first substrate 110 and/or the second substrate 120. Therefore, on the first substrate 110 and the second substrate 120, a plurality of types of transistors having different breakdown voltages (having different film thicknesses of gate insulating films) are mounted together, and the manufacturing process becomes complicated.

From such a viewpoint, in the photoelectric conversion device according to the present embodiment, the functional blocks configured by the transistors having a low withstand voltage are integrated on the third substrate 130, and the functional blocks configured by the transistors having a high withstand voltage are arranged on the first substrate 110 and the second substrate 120. With this configuration, the first substrate 110 and the second substrate 120 may be configured only by transistors having a high withstand voltage, and the manufacturing process of the first substrate 110 and the second substrate 120 may be simplified. Thus, the manufacturing cost of the photoelectric conversion device may be reduced.

As described above, according to the present embodiment, similarly to the first embodiment, in the photoelectric conversion device including the plurality of substrates, it is possible to improve the performance of the peripheral circuit, and it is possible to realize the improvement of the signal quality and the cost reduction. In addition, when the transistors provided over the substrates are unified into one of a transistor with low withstand voltage and a transistor with high withstand voltage, the number of manufacturing steps of the substrates may be reduced, so that manufacturing cost may be further reduced.

### Fifth Embodiment

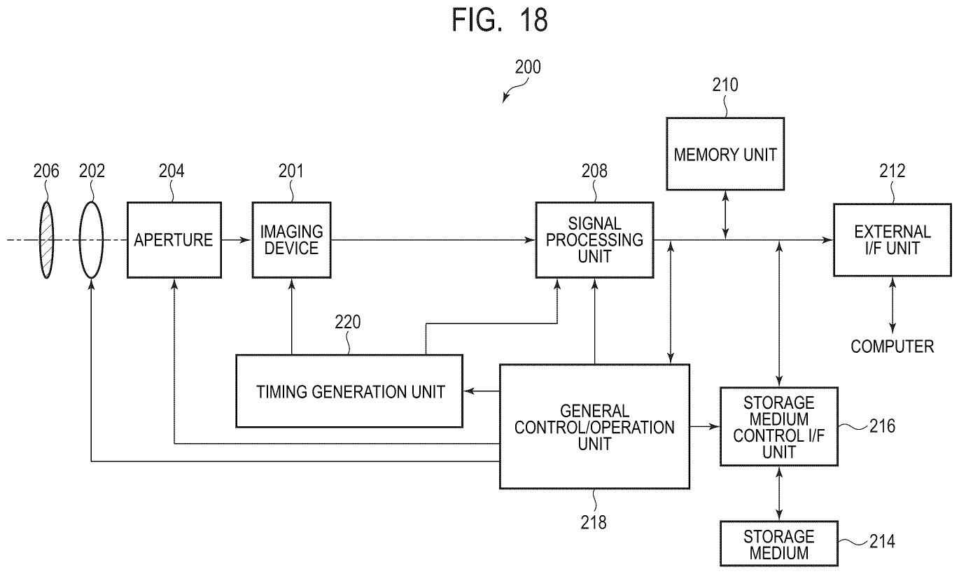

A photoelectric conversion system according to a fifth embodiment will be described with reference to FIG. 18. FIG. 18 is a block diagram illustrating a schematic configuration of a photoelectric conversion system according to the present embodiment.

The photoelectric conversion device 100 described in the first to fourth embodiments may be applied to various photoelectric conversion systems. Examples of applicable photoelectric conversion systems include digital still cameras, digital camcorders, surveillance cameras, copying machines, facsimiles, mobile phones, on-vehicle cameras, observation satellites, and the like. A camera module including an optical system such as a lens and an imaging device is also included in the photoelectric conversion system. FIG. 18 exemplifies a block diagram of a digital still camera as one of these.

The photoelectric conversion system 200 illustrated in FIG. 18 includes an imaging device 201, a lens 202 that forms an optical image of an object on the imaging device 201, an aperture 204 that changes the amount of light passing through the lens 202, and a barrier 206 that protects the lens 202. The lens 202 and the aperture 204 constitute an optical system that focuses light onto the imaging device 201. The imaging device 201 is the photoelectric conversion device 100 described in any of the first to fourth embodiments, and converts the optical image formed by the lens 202 into image data.

The photoelectric conversion system 200 further includes a signal processing unit 208 that processes an output signal output from the imaging device 201. The signal processing unit 208 generates image data from the digital signal output from the imaging device 201. Further, the signal processing unit 208 performs various corrections and compressions as necessary and outputs the processed image data. The imaging device 201 may include an AD conversion unit that generates a digital signal to be processed by the signal processing unit 208. The AD conversion unit may be formed on a semiconductor layer (semiconductor substrate) on which the photoelectric conversion unit of the imaging device 201 is formed or may be formed on a semiconductor layer different from the semiconductor layer on which the photoelectric conversion unit of the imaging device 201 is formed. The signal processing unit 208 may be formed on the same semiconductor layer as the imaging device 201.

The photoelectric conversion system 200 further includes a memory unit 210 for temporarily storing image data and an external interface unit (external I/F unit) 212 for communicating with an external computer or the like. The photoelectric conversion system 200 further includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photoelectric conversion system 200 or may be detachable.

The photoelectric conversion system 200 further includes a general control/operation unit 218 that performs various calculations and controls the entire digital still camera, and a timing generation unit 220 that outputs various timing signals to the imaging device 201 and the signal processing unit 208. Here, the timing signal or the like may be input from the outside, and the photoelectric conversion system 200 may include at least the imaging device 201 and the signal processing unit 208 that processes the output signal output from the imaging device 201.

The imaging device 201 outputs an imaging signal to the signal processing unit 208. The signal processing unit 208 performs predetermined signal processing on the imaging signal output from the imaging device 201 and outputs the processed image data. The signal processing unit 208 generates an image using the imaging signal.

As described above, according to the present embodiment, it is possible to realize a photoelectric conversion system to which the photoelectric conversion device 100 according to any of the first to fourth embodiments is applied.

### Sixth Embodiment

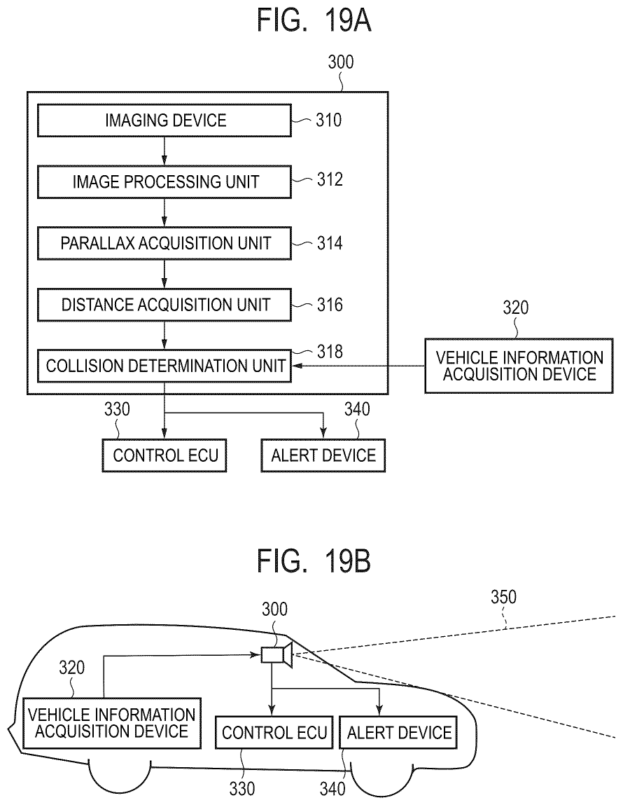

The photoelectric conversion system and a movable object according to a sixth embodiment will be described with reference to FIG. 19A and FIG. 19B. FIG. 19A is a diagram illustrating a configuration of a photoelectric conversion system according to the present embodiment. FIG. 19B is a diagram illustrating a configuration of a movable object according to the present embodiment.

FIG. 19A illustrates an example of a photoelectric conversion system related to an on-vehicle camera. The photoelectric conversion system 300 includes an imaging device 310. The imaging device 310 is the photoelectric conversion device 100 according to any one of the first to fourth embodiments. The photoelectric conversion system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The photoelectric conversion system 300 further includes a distance acquisition unit 316 that calculates a distance to an object based on the calculated parallax, and a collision determination unit 318 that determines whether there is a collision possibility based on the calculated distance. Here, the parallax acquisition unit 314 and the distance acquisition unit 316 are an example of a distance information acquisition unit that acquires distance information to the object. That is, the distance information is information related to a parallax, a defocus amount, a distance to the object, and the like. The collision determination unit 318 may determine the collision possibility using any of the distance information. The distance information acquisition unit may be realized by dedicatedly designed hardware or may be realized by a software module. Further, it may be realized by a field programmable gate array (FPGA), an application specific integrated circuit (ASIC), or the like, or may be realized by a combination of these.

The photoelectric conversion system 300 is connected to a vehicle information acquisition device 320 and may acquire vehicle information such as a vehicle speed, a yaw rate, and a steering angle. Further, the photoelectric conversion system 300 is connected to a control ECU 330 which is a control device that outputs a control signal for generating a braking force to the vehicle based on the determination result of the collision determination unit 318. The photoelectric conversion system 300 is also connected to an alert device 340 that issues an alert to the driver based on the determination result of the collision determination unit 318. For example, when the determination result of the collision determination unit 318 indicates that the possibility of collision is high, the control ECU 330 performs vehicle control to avoid collision and reduce damage by, for example, applying a brake, returning an accelerator, or suppressing engine output. The alert device 340 gives an alert to the user by sounding an alarm such as a sound, displaying alert information on a screen of a car navigation system or the like, giving vibration to a seat belt or a steering wheel, or the like.

In the present embodiment, an image of the surroundings of the vehicle, for example, the front or the rear is captured by the photoelectric conversion system 300. FIG. 19B illustrates the photoelectric conversion system in the case of capturing an image in front of the vehicle (imaging range 350). The vehicle information acquisition device 320 sends instructions to the photoelectric conversion system 300 or the imaging device 310. With such a configuration, the accuracy of distance measurement may be further improved.

Although an example in which control is performed so as not to collide with another vehicle has been described above, the present embodiment is also applicable to control in which automatic driving is performed so as to follow another vehicle, control in which automatic driving is performed so as not to protrude from a lane, and the like. Further, the photoelectric conversion system is not limited to a vehicle such as an own vehicle, and may be applied to, for example, other mobile objects (mobile devices), such as, for example, a ship, an aircraft, or an industrial robot. In addition, the present embodiment is not limited to the movable object and may be widely applied to equipment using object recognition, such as intelligent transport systems (ITS).

### Seventh Embodiment

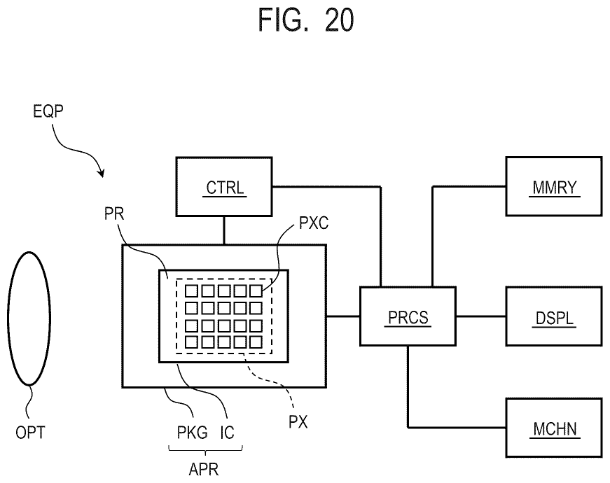

An equipment according to a seventh embodiment will be described with reference to FIG. 20. FIG. 20 is a block diagram illustrating a schematic configuration of an equipment according to the present embodiment.

FIG. 20 is a schematic diagram illustrating an equipment EQP including a photoelectric conversion device APR. The photoelectric conversion device APR has the function of the photoelectric conversion device 100 according to any of the first to fourth embodiments. All or part of the photoelectric conversion device APR is a semiconductor device IC. The photoelectric conversion device APR of the present example may be used as, for example, an image sensor, an auto focus (AF) sensor, a photometric sensor, or a distance measuring sensor. The semiconductor device IC includes a pixel region PX in which pixel circuits PXC each including a photoelectric conversion unit are arranged in a matrix. The semiconductor device IC may include a peripheral region PR around the pixel region PX. A circuit other than the pixel circuit may be arranged in the peripheral region PR.

The photoelectric conversion device APR may have a structure (chip stacked structure) in which a first semiconductor chip provided with a plurality of photoelectric conversion units and a second semiconductor chip provided with peripheral circuits are stacked. Each of the peripheral circuits on the second semiconductor chip may be column circuits corresponding to pixel columns of the first semiconductor chip. The peripheral circuits on the second semiconductor chip may be matrix circuits corresponding to pixels or pixel blocks on the first semiconductor chip. As the connection between the first semiconductor chip and the second semiconductor chip, a through electrode (through silicon via (TSV)), an inter-chip interconnection by direct bonding of a conductor such as copper, a connection by a micro bump between the chips, a connection by wire bonding, or the like may be employed.

The photoelectric conversion device APR may include a package PKG that accommodates the semiconductor device IC in addition to the semiconductor device IC. The package PKG may include a base body to which the semiconductor device IC is fixed, a lid body such as glass facing the semiconductor device IC, and connection members such as bonding wires or bumps for connecting terminals provided on the base body and terminals provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR, and is, for example, a lens, a shutter, or a mirror. The control device CTRL controls the photoelectric conversion device APR and is, for example, a semiconductor device such as an ASIC. The processing device PRCS processes a signal output from the photoelectric conversion device APR and constitutes an analog front end (AFE) or a digital front end (DFE). The processing unit PRCS is a semiconductor device such as a central processing unit (CPU) or an ASIC. The display device DSPL may be an electroluminescent (EL) display device or a liquid crystal display device that displays information (image) obtained by the photoelectric conversion device APR. The storage device MMRY may be a magnetic device or a semiconductor device that stores information (image) obtained by the photoelectric conversion device APR. The storage device MMRY may be a volatile memory such as an SRAM or a DRAM, or a nonvolatile memory such as a flash memory or a hard disk drive. The mechanical device MCHN may include a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, it is preferable that the equipment EQP further includes a storage device MMRY and a processing device PRCS separately from the storage circuit unit and the arithmetic circuit unit included in the photoelectric conversion device APR.

The equipment EQP illustrated in FIG. 20 may be an electronic device such as an information terminal (for example, a smartphone or a wearable terminal) having a photographing function or a camera (for example, an interchangeable lens camera, a compact camera, a video camera, and a monitoring camera). The mechanical device MCHN in the camera may drive components of the optical device OPT for zooming, focusing, and shutter operation. The equipment EQP may be a transportation device (movable object) such as a vehicle, a ship, or an aircraft. The equipment EQP may be a medical device such as an endoscope or a computed tomography (CT) scanner.

The mechanical device MCHN in the transportation device may be used as a mobile device. The equipment EQP as a transportation device is suitable for transporting the photoelectric conversion device APR, or for assisting and/or automating operation (manipulation) by an imaging function. The processing device PRCS for assisting and/or automating driving (manipulation) may perform processing for operating the mechanical device MCHN as a mobile device based on information obtained by the photoelectric conversion device APR.

The photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP.

### Modified Embodiments

The present disclosure is not limited to the above embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present disclosure.

In the first to fourth embodiments, the global shutter type photoelectric conversion device including the memory unit 30 has been described, but the photoelectric conversion device to which the present technology is applicable is not limited thereto. For example, the transfer of the pixel signals from the pixel unit 10 to the memory unit 30 does not necessarily need to be performed collectively or in units of blocks and may be performed sequentially in units of rows. The photoelectric conversion device does not necessarily include the memory unit 30 and may be a rolling shutter type photoelectric conversion device.

Further, the circuit configuration of the pixel 12 described in the above embodiment is an example and may be appropriately changed. For example, although the pixels 12 each including a plurality of photoelectric conversion elements are described in the above embodiments, the number of photoelectric conversion elements included in each pixel 12 is not necessarily plural and may be one. In addition, the pixel 12 does not necessarily have to include the select transistor M4. The capacitance value of the node FD may be switchable.

The photoelectric conversion systems described in the fifth and sixth embodiments are examples of photoelectric conversion systems to which the photoelectric conversion device of the present disclosure may be applied, and the photoelectric conversion system to which the photoelectric conversion device of the present disclosure may be applied is not limited to the configuration illustrated in FIG. 18 and FIG. 19A.

According to the present disclosure, in a photoelectric conversion device including a plurality of substrates, it is possible to improve performance of a peripheral circuit and to realize improvement in signal quality and cost reduction.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-023556, filed Feb. 17, 2025, which is hereby incorporated by reference herein in its entirety.

What is claimed is:

1. A photoelectric conversion device comprising:
a pixel unit including a photoelectric conversion element and configured to output a signal according to incident light to the photoelectric conversion element; and
a pixel driving circuit configured to drive the pixel unit,
wherein the pixel driving circuit includes a circuit including a complementary connection between a first transistor of a first conductivity type provided on a first substrate and a second transistor of a second conductivity type provided on a second substrate.

2. The photoelectric conversion device according to claim 1, further comprising: a first control circuit configured to control the pixel driving circuit,
wherein the first control circuit is provided on the first substrate.

3. The photoelectric conversion device according to claim 1, further comprising: a first control circuit configured to control the pixel driving circuit,
wherein the first control circuit includes a circuit including a complementary connection between a third transistor of the first conductivity type provided on the first substrate and a fourth transistor of the second conductivity type provided on the second substrate.

4. The photoelectric conversion device according to claim 1, further comprising: a first control circuit configured to control the pixel driving circuit,
wherein the first control circuit is provided on a third substrate.

5. The photoelectric conversion device according to claim 1, further comprising:
a memory unit configured to hold a signal output from the pixel unit; and
a memory driving circuit provided on the second substrate and configured to drive the memory unit.

6. The photoelectric conversion device according to claim 1, further comprising:
a memory unit configured to hold a signal output from the pixel unit; and
a memory driving circuit configured to drive the memory unit,
wherein the memory driving circuit includes a circuit including a complementary connection between a fifth transistor of the first conductivity type provided on the first substrate and a sixth transistor of the second conductivity type provided on the second substrate.

7. The photoelectric conversion device according to claim 5,
wherein the pixel unit includes a seventh transistor of the first conductivity type that constitutes a source follower circuit and configured to output a signal according to an output of the photoelectric conversion element, and
wherein the memory unit includes a holding portion configured to hold a signal output from the pixel unit and an eighth transistor of the second conductivity type that constitutes a source follower circuit and configured to output a signal according to an output of the holding portion.

8. The photoelectric conversion device according to claim 6, further comprising: a second control circuit configured to control the memory driving circuit,
wherein the second control circuit is provided on the second substrate.

9. The photoelectric conversion device according to claim 5, further comprising: a second control circuit configured to control the memory driving circuit,
wherein the second control circuit includes a circuit including a complementary connection between a ninth transistor of the first conductivity type provided on the first substrate and a tenth transistor of the second conductivity type provided on the second substrate.

10. The photoelectric conversion device according to claim 1, further comprising: a signal processing circuit provided on a third substrate and configured to process a signal output from the pixel unit.

11. The photoelectric conversion device according to claim 1,
wherein each of transistors provided on the first substrate has the first conductivity type, and
wherein each of transistors provided on the second substrate has the second conductivity type.

12. The photoelectric conversion device according to claim 4, wherein gate insulating films of transistors provided on the first substrate and the second substrate among transistors constituting the pixel driving circuit are thicker than gate insulating films of transistors provided on the third substrate.

13. The photoelectric conversion device according to claim 1, wherein the pixel unit is provided on the first substrate.

14. The photoelectric conversion device according to claim 1, further comprising: a signal processing circuit configured to process a signal output from the pixel unit,
wherein the signal processing circuit includes a circuit including a complementary connection between an eleventh transistor of the first conductivity type provided on the first substrate and a twelfth transistor of the second conductivity type provided on the second substrate.

15. The photoelectric conversion device according to claim 14, further comprising a third control circuit configured to control the signal processing circuit,
wherein the third control circuit is provided on the first substrate.

16. The photoelectric conversion device according to claim 14, further comprising: a third control circuit configured to control the signal processing circuit,
wherein the third control circuit includes a circuit including a complementary connection between a thirteenth transistor of the first conductivity type provided on the first substrate and a fourteenth transistor of the second conductivity type provided on the second substrate.

17. The photoelectric conversion device according to claim 1, wherein the transistor of the first conductivity type provided on the first substrate and the transistor of the second conductivity type provided on the second substrate are electrically connected to each other via a plurality of connection portions arranged in parallel.

18. A photoelectric conversion system comprising:
the photoelectric conversion device according to claim 1; and
a signal processing device configured to process a signal output from the photoelectric conversion device.

19. A movable object comprising:
the photoelectric conversion device according to claim 1;
a distance information acquisition unit configured to acquire distance information to an object from a parallax image based on a signal from the photoelectric conversion device; and
a control unit configured to control the movable object based on the distance information.

20. An equipment comprising:
the photoelectric conversion device according to claim 1; and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
